(19) United States
(12) Patent Application Publication
(10) Pub. No.: US 2026/0350349 A1
(43) Pub. Date: Nov. 5, 2026

(54) Simulation Warmup

(71) Applicant: PassiveLogic, Inc., Holladay, UT (US)

(72) Inventors: Troy Aaron Harvey, Holladay, UT (US); Jeremy David Fillingim, Salt Lake City, UT (US); Porter Jonas Child, Holladay, UT (US)

(21) Appl. No.: 19/736,368

(22) Filed: Jul. 9, 2026

Related U.S. Application Data
(63) Continuation of application No. 17/567,275, filed on Feb. 9, 2022.

(51) Int. Cl. G06N 3/044; G06F 30/27; G06N 3/084; G06N 3/09

(52) U.S. Cl. CPC G06N 3/044; G06F 30/27; G06N 3/084; G06N 3/09

(57) ABSTRACT

A machine learning optimizer that runs a simulator uses time-state waves as input to determine initial node values for the simulator in an official simulation run, producing time state waves as a result. A learning model uses the input and output as a training example by reversing the time-state waves, using the output from the simulator as input, obtains output, reversed the output, and then uses the reversed output as ground truth to compare to desired output of the simulation.

### FIELD OF INVENTION

The present disclosure relates to machine learning techniques, more specifically, using one simulation model using one machine learning technique to train another model using a different machine learning technique.

### SUMMARY

This summary is provided to introduce a selection of concepts in a simplified form that are further described below in the Detailed Description section. This summary does not identify required or essential features of the claimed subject matter. The innovation is defined with claims, and to the extent this Summary conflicts with the claims, the claims should prevail.

In general, some technologies described herein describe training a learning model using an optimizer.

In embodiments, a computer-enabled learning model training system is disclosed. The system comprises: a processor; a memory in operable communication with the processor, computing code associated with the processor configured to create a simulator trainer; an optimizer that determines initial node values for a simulator, the simulator comprising nodes with values; the simulator that uses an input time series from time t=(−n) to time t=(0) as input, and outputs for the nodes an output time series from time t=(−n) to time t=(0); a reverser that reverses the input time series to time t=(0) to t=(−n), to produce a reversed input time series and reverses the output time series to time t=(0) to t=(−n); and a learning model that uses the reversed input time series as training input and uses selected values of the output time series at t=(−n) as a ground truth for a cost function associated with the learning model.

In embodiments, the simulator is a heterogenous neural network.

In embodiments, the system further comprises a cost function determiner that uses selected node values from the output time series as an input into a cost function, and wherein the cost function determiner further comprises the cost function using the ground truth as input into the cost function.

In embodiments, a cost derived from the cost function is used by the optimizer to determine subsequent initial node values.

In embodiments, further comprising an iterator which iteratively runs the optimizer, the simulator, and the learning model until a stop state is reached.

In embodiments, when the stop state is reached, the initial node values are used as input into a starting state estimation simulation.

In embodiments, the starting state estimation simulation is run from time t=(−n) to time t=(0); wherein a state simulation is then run from time t(0) to t(m); the state simulation produces an output that can be used to produce a control sequence, and wherein the control sequence is used to run a device modeled by the state simulation.

In embodiments, the Learning Model is a neural network.

In embodiments, the neural network is a Recurrent Neural Network.

In embodiments, a computer-enabled method to train a learning model using an optimizer model implemented in a computing system is disclosed, the method comprising one or more processors and one or more memories coupled to the one or more processors, the one or more memories comprising computer-executable instructions for causing the computing system to perform operations comprising: running an optimizer to determine initial simulator node values; running a simulator using inputs and the initial simulator node values producing simulator outputs; comparing selected node values from the simulator outputs to an desired node values producing a cost; reversing the selected node values, producing a reversed selected node values; reversing the inputs of the simulator producing a reversed simulator input; using the reversed selected node values and the reversed simulator input as training input into a learning model; and running the learning model.

In embodiments, running the learning model produces a reversed time series as learning model output.

In embodiments, the learning model output at time t(−n) is compared with the initial simulator node values in a cost function.

In embodiments, the cost is derived from the cost function, and wherein the cost is used for backpropagation within the learning model.

In embodiments, the simulator is a heterogenous neural network.

In embodiments, the inputs comprises weather data over time.

In embodiments, the selected node values are temperature of areas inside a space that the simulator is modeling.

In embodiments, reversing the inputs of the simulator comprise reversing time series originally from t=(−n) to time=(0) to time t=(0) to t=(−n), to produce a reversed time series.

In embodiments, a computer-readable storage medium configured with instructions is disclosed, which upon execution by one or more processors to perform a method for training a simulator, the method comprising: running an optimizer to determine initial simulator node values; running a simulator using inputs and the initial simulator node values producing simulator output; comparing selected node values from the simulator outputs to an desired node values producing a cost; reversing the selected node values, producing a reversed selected node values; reversing the inputs of the simulator producing a reversed simulator input; using the reversed selected node values and the reversed simulator input as training input into a learning model; and running the learning model.

In embodiments, the learning model output at time t=(−n) is compared with the simulator output at time t=(0) for a learning model cost function, and wherein a cost derived from the learning model cost function is used for backpropagation within the learning model.

In embodiments, the learning model is a Recurrent Neural Network.

These, and other, aspects of the invention will be better appreciated and understood when considered in conjunction with the following description and the accompanying drawings. The following description, while indicating various embodiments of the embodiments and numerous specific details thereof, is given by way of illustration and not of limitation. Many substitutions, modifications, additions or rearrangements may be made within the scope of the embodiments, and the embodiments includes all such substitutions, modifications, additions or rearrangements.

### BRIEF DESCRIPTION OF THE FIGURES

Non-limiting and non-exhaustive embodiments of the present embodiments are described with reference to the following FIGURES, wherein like reference numerals refer to like parts throughout the various views unless otherwise specified.

FIG. 1 discloses a relationship between inputs and outputs of a simulator and a learning model during a training process with which embodiments disclosed herein may be implemented.

FIG. 2 discloses interaction between a learning model and a simulator when the learning model has been fully trained with which embodiments disclosed herein may be implemented.

FIG. 2A discloses interactions between an initial value simulation, a starting state estimation simulation, and a state simulation with which embodiments disclosed herein may be implemented.

FIG. 2B discloses interaction between an optimizer and a heterogenous node system with which embodiments disclosed herein may be implemented.

FIG. 3 discloses a computing system in conjunction with which described embodiments can be implemented.

FIG. 4 discloses a distributed computing system with which embodiments disclosed herein may be implemented.

FIG. 5 discloses an optimizer loop with inputs and outputs with which embodiments disclosed herein may be implemented.

FIG. 6 discloses a simulator state with outputs with which embodiments disclosed herein may be implemented.

FIG. 7 discloses a learning model loop with inputs and outputs with which embodiments disclosed herein may be implemented.

FIG. 8 discloses a heterogenous node loop with inputs and outputs, including end-of-run values with which embodiments disclosed herein may be implemented.

FIG. 9 discloses training an RNN with which embodiments disclosed herein may be implemented.

FIG. 10 discloses a trained RNN with which embodiments disclosed herein may be implemented.

FIGS. 11A and 11B disclose a flowchart describing a method to train a learning model using an optimizer with which embodiments disclosed herein may be implemented.

FIG. 12 discloses exemplary simulator nodes with which embodiments disclosed herein may be implemented.

FIG. 13 discloses exemplary learning model inputs and outputs with which embodiments disclosed herein may be implemented.

FIG. 14 discloses an exemplary node with which embodiments disclosed herein may be implemented.

FIG. 15A discloses an exemplary starting state estimation simulation flow with which embodiments disclosed herein may be implemented.

FIG. 15B discloses an exemplary warmup estimation simulation flow with which embodiments disclosed herein may be implemented.

FIG. 16 discloses exemplary node values in different simulations with which embodiments disclosed herein may be implemented.

FIG. 17 discloses an exemplary flow chart that shows a sanity check to ensure initial starting state estimation values are valid.

FIG. 18 discloses an exemplary simulation starting state estimation system with which embodiments disclosed herein may be implemented.

Corresponding reference characters indicate corresponding components throughout the several views of the drawings. Skilled artisans will appreciate that elements in the FIGURES are illustrated for simplicity and clarity and have not necessarily been drawn to scale. For example, the dimensions of some of the elements in the figures may be exaggerated relative to other elements to help to improve understanding of various embodiments. Also, common but well-understood elements that are useful or necessary in a commercially feasible embodiment are often not depicted in order to facilitate a less obstructed view of these various embodiments.

### DETAILED DESCRIPTION

Disclosed below are representative embodiments of methods, computer-readable media, and systems having particular applicability to systems and methods for warming up a simulation. Described embodiments implement one or more of the described technologies.

In the following description, numerous specific details are set forth in order to provide a thorough understanding of the present embodiments. It will be apparent, however, to one having ordinary skill in the art that the specific detail need not be employed to practice the present embodiments. In other instances, well-known materials or methods have not been described in detail in order to avoid obscuring the present embodiments. “one embodiment”, “an embodiment”, “one example” or “an example” means that a particular feature, structure or characteristic described in connection with the embodiment or example is included in at least one embodiment of the present embodiments. Thus, appearances of the phrases “in one embodiment”, “in an embodiment”, “one example” or “an example” in various places throughout this specification are not necessarily all referring to the same embodiment or example. Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order.

For convenience, the present disclosure may be described using relative terms including, for example, left, right, top, bottom, front, back, upper, lower, up, and down, as well as others. It is to be understood that these terms are merely used for illustrative purposes and are not meant to be limiting in any manner.

In addition, it is appreciated that the figures provided herewith are for explanation purposes to persons ordinarily skilled in the art and that the drawings are not necessarily drawn to scale. To aid the Patent Office and any readers of any patent issued on this application in interpreting the claims appended hereto, applicants may wish to note that they do not intend any of the appended claims or claim elements to invoke 35 U.S.C. 112(f) unless the words “means for” or “step for” are explicitly used in the particular claim.

Embodiments in accordance with the present embodiments may be implemented as an apparatus, method, or computer program product. Accordingly, the present embodiments may take the form of an entirely hardware embodiment, an entirely software embodiment (including firmware, resident software, micro-code, etc.), or an embodiment combining software and hardware aspects that may be referred to as a “system.” Furthermore, the present embodiments may take the form of a computer program product embodied in any tangible medium of expression having computer-usable program code embodied in the medium.

Any combination of one or more computer-usable or computer-readable media may be utilized. For example, a computer-readable medium may include one or more of a portable computer diskette, a hard disk, a random access memory (RAM) device, a read-only memory (ROM) device, an erasable programmable read-only memory (EPROM or Flash memory) device, a portable compact disc read-only memory (CDROM), an optical storage device, and a magnetic storage device. Computer program code for carrying out operations of the present embodiments may be written in any combination of one or more programming languages.

The flowchart and block diagrams in the flow diagrams illustrate the architecture, functionality, and operation of possible implementations of systems, methods, and computer program products according to various embodiments of the present embodiments. In this regard, each block in the flowchart or block diagrams may represent a module, segment, or portion of code, which comprises one or more executable instructions for implementing the specified logical function(s). It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions. These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

“Optimize” means to improve, not necessarily to perfect. For example, it may be possible to make further improvements in a value or an algorithm which has been optimized.

As used herein, the terms “comprises,” “comprising,” “includes,” “including,” “has,” “having,” or any other variation thereof, are intended to cover a non-exclusive inclusion. For example, a process, article, or apparatus that comprises a list of elements is not necessarily limited to only those elements but may include other elements not expressly listed or inherent to such process, article, or apparatus.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present). “Program” is used broadly herein, to include applications, kernels, drivers, interrupt handlers, firmware, state machines, libraries, and other code written by programmers (who are also referred to as developers) and/or automatically generated. “Optimize” means to improve, not necessarily to perfect. For example, it may be possible to make further improvements in a program or an algorithm which has been optimized. “Determine” means to get a good idea of, not necessarily to achieve the exact value. For example. It may be possible to make further improvements in a value or algorithm which has already been determined.

Additionally, any examples or illustrations given herein are not to be regarded in any way as restrictions on, limits to, or express definitions of any term or terms with which they are utilized. Instead, these examples or illustrations are to be regarded as being described with respect to one particular embodiment and as being illustrative only. Those of ordinary skill in the art will appreciate that any term or terms with which these examples or illustrations are utilized will encompass other embodiments which may or may not be given therewith or elsewhere in the specification and all such embodiments are intended to be included within the scope of that term or terms. Language designating such nonlimiting examples and illustrations includes, but is not limited to: “for example,” “for instance,” “e.g.,” and “in one embodiment.”

A “cost function,” generally, is a function determines how close a simulation model answer is to the desired answer—the ground truth. That is, tt quantifies the error between the predicted value and the desired value. This cost function returns a cost. The cost function may use a least squares function, a Mean Error (ME), Mean Squared Error (MSE), Mean Absolute Error (MAE), a Categorical Cross Entropy Cost Function, a Binary Cross Entropy Cost Function, and so on, to arrive at the answer. In some implementations, the cost function is a loss function. In some implementations, the cost function is a threshold, which may be a single number that indicates the simulated truth curve is close enough to the ground truth. In other implementations, the cost function may be a slope. The slope may also indicate that the simulated truth curve and the ground truth are of sufficient closeness. When a cost function is used, it may be time variant. It also may be linked to factors such as user preference, or changes in the physical model. The cost function applied to the simulation engine may comprise models of any one or more of the following: energy use, primary energy use, energy monetary cost, human comfort, the safety of building or building contents, the durability of building or building contents, microorganism growth potential, system equipment durability, system equipment longevity, environmental impact, and/or energy use CO2 potential. The cost function may utilize a discount function based on discounted future value of a cost. In some embodiments, the discount function may devalue future energy as compared to current energy such that future uncertainty is accounted for, to ensure optimized operation over time. The discount function may devalue the future cost function of the control regimes, based on the accuracy or probability of the predicted weather data and/or on the value of the energy source on a utility pricing schedule, or the like. A cost may be derived from a cost function This cost may be a single number. A “goal function” may read in a cost (a value from a cost function) and determine if that cost meets criteria such that a goal has been reached, such that the simulation iterations stop. Such criteria may be the cost reaching a certain value, being higher or lower than a certain value, being between two values, etc. A goal function may also look at the time spent running the simulation model overall and/or how may iterations have been made to determine if the goal function has been met.

A “machine learning algorithm” or “optimization method” is used to determine the next set of inputs after running a simulation model. These machine learning algorithms or optimization methods may include Gradient Descent, methods based on Newton's method, and inversions of the Hessian using conjugate gradient techniques, Evolutionary computation such as Swarm Intelligence, Bee Colony optimization; self-organizing migrating algorithm (SOMA), Particle Swarm, Non-linear optimization techniques, and other methods known by those of skill in the art. A “state” as used herein may be Air Temperature, Radiant Temperature, Atmospheric Pressure, Sound Pressure, Occupancy Amount, Indoor Air Quality, CO2 concentration, Light Intensity, or another state that can be measured and controlled.

The deep physics networks that are used herein are a type of structured similar to neural networks. But unlike the homogeneous activation functions of neural nets, each neuron comprises unique physical equations (for the equipment model) or resistance/capacitance values (for the building model). Once configured, known sensors are fed into their corresponding nodes in the network. Once the network is trained, any location in the thermodynamic system can be queried to extract data about the model at that point. The figure “Possible Equipment Model Implementation” shows one portion of a database structure that might hold queryable data for an equipment model. Querying a model can also be called introspecting. Similar data structure exist for building models. This process provides powerful generalized data fusion, data synthesis, and quality assessment through inference even where no sensors exist—for any thermodynamic system. The same mechanism enables model optimization, and time series generated from the models can then be used for real-time sequence generation and fault detection. To automate a structure, a digital twin version (the structure simulation) of the structure is created. A matching digital twin version of the equipment in the building (the equipment simulation) is created as well (the equipment simulation). The equipment model comprises nodes that represent the individual material layers of the building and their resistance and capacitance. These are formed into parallel and branchless neural network strings that propagate heat (or other state values) through them. The equipment model comprises nodes that represent equipment, their connections, and outside influences on the equipment, such as weather. Nodes have physics equations that describe equipment state change. Equipment nodes may also have state input(s) and state output(s), state parameters with values, allowable state parameter values, state input location data, and state output location data. The location data can be cross-referenced to the thermodynamic building model locations. In embodiments, the equipment nodes may form control loops. These nodes inputs and outputs along along with the connections between the equipment form a heterogenous neural network. State information flows through the model following physical rules.

Conceptually, running a structure simulation model comprises inserting some amount of some measurable state into the building. This can be temperature, humidity, acoustic, vibration, magnetic, light, pressure, moisture, etc. This state then propagates through the different layers, affecting the structure. This illustrative example uses temperature to describe aspects of the system and methods. (brick, insulation, drywall, etc.) heating up rooms, as represented by inside nodes. An outside node is associated with a time heat curve T. The curve value at time T₁ is injected into one or more outside nodes. This temperature is propagated through the building (by the values of the nodes of the simulation neural nets) . The outside of the building (say, brick), has its temperature modified by the outside node and known aspects of how heat transfers through brick as found in the brick node. The brick then heats up the next layer, perhaps insulation. This continues throughout the building until an inside node is reached. At inside nodes, other functions can be applied, such as those that represent lighting and people (warmth) within the zone. State information continues to propagate until another outside layer is reached, with individual node parameter values representing the heating present in the building at time T₁. In some embodiments, each outer surface has its own time temperature curve. In some embodiments a building is deconstructed into smaller subsystems, (or zones) so rather than propagating temperature through the entire structure, only a portion of the structure is affected by a given input. In some implementations, the digital twin models are built on a controller that is associated with the building being controlled. In some instances, the controller is embedded in the controlled building and is used to automate the building. A controller may comprise a simulation engine that itself comprises a model of the controlled system the controller is in, or a model of the equipment in the controlled system the controller is in. This model may be called the “physical model.” This physical model may itself comprise past regressions and a cost function. The past regressions are instances of these model being run in the past and the results. The controlled system has at least one sensor whose value can be used to calibrate the physical model(s) by checking how close the model value at the sensor location is to the simulated sensor value equivalent in the physical models. A cost function may be used to determine the distance between the sensor value and the simulated sensor value equivalent. This information can then be used to refine the physical models. This Controller-Controlled system loop may be implemented without use of the internet. The Controller may control and/or run a Local Area Network (LAN) with which it talks to sensors and other resources. The Controller may be hardwired into the sensors and other resources, or there may be a combined system, with some resources hardwired, and other resources which connect to the LAN. A “simulation model” may be a resource model or a building model.

A “machine learning algorithm” or “optimization method” is used to determine the next set of inputs after running a simulation model. These machine learning algorithms or optimization methods may include Gradient Descent, methods based on Newton's method, and inversions of the Hessian using conjugate gradient techniques, Evolutionary computation such as Swarm Intelligence, Bee Colony optimization; self-organizing migrating algorithm (SOMA), Particle Swarm, Non-linear optimization techniques, and other methods known by those of skill in the art. A “state” as used herein may be Air Temperature, Radiant Temperature, Atmospheric Pressure, Sound Pressure, Occupancy Amount, Indoor Air Quality, CO2 concentration, Light Intensity, or another state that can be measured and controlled.

The technical character of embodiments described herein will be apparent to one of ordinary skill in the art, and will also be apparent in several ways to a wide range of attentive readers. Some embodiments address technical activities that are rooted in computing technology, such as determining more efficient ways to perform simulations. These simulations may simulate energy flow in a building or other structure. The energy flow simulation may produce control sequences that allow a building to run with much more energy efficiency. The simulations themselves may be able to run much quicker by being able to be warmed up to a reasonable value, and by performing that warmup very quickly, more efficiently using the computer processor and memory. Other advantages based on the technical characteristics of the teachings will also be apparent to one of skill from the description provided.

### 1. Overview

To perform an informative building simulation starting at t=0 and going into the future, a simulation of the building itself cannot be in a random state. To see why, consider the following example. Imagine starting a simulation with every node in the building at −100 degrees C. Rather than a simulation of such a building being predictive of future reality, any reasonably long simulation would spend the entire simulation time heating up to ambient temperature. Furthermore, the output of the nodes representing zone temperatures would be useless lines starting at −100 degrees C, and then steadily heating up. The actual building, from time t=0 on, will consist of precise oscillations of temperature based on weather inputs, building inter-dynamics and human interaction.

Setting all the nodes to ambient temperature at t=0 also fails as the dynamics of a building consist of complex relationships, which include resistance of materials, capacitance of masses, solar absorption, etc. The various zones in a building are never all the same, and their relationships are complex. Starting all nodes in a model at the same temperature is too simplified to get meaningful simulator output from t=0 on. Again, it might take the entire simulation before the dynamics of the building have had time to stabilize and reflect reality.

Even when historical temperature readings exist, there are only a small subset of nodes that represent an area in the building with a temperature sensor. Empirical historical data may only exist for two or three percent of the locations in a building represented by nodes. Therefore, an estimate from such sparse data may lead to most nodes having values very far off from what their corresponding actual values may be. Again, it might take the entire simulation before the dynamics of the building have had time to overwrite the estimation errors and reflect reality. Running the simulation for a longer time may be very time-and resource consuming. Such models are by their very nature users of massive amounts of computer resources and time. Using techniques disclosed herein will use the little empirical data we have to infer correct temperatures at t=0 for the unknown nodes in a building (or similar structure) while reducing use of valuable computer resources. The state estimation simulation methods and systems taught here run much quicker to achieve a reasonable starting point than running a simulation for an extended period of time.

Learning models are very powerful at solving difficult problems. However, such models must be trained with many sets of training data before they are able to offer a reasonable solution. Acquiring sufficient training examples is often difficult, and sometimes insurmoutable. Developing a training set involves acquiring and/or generating many examples of input data that can then generate meaningful output data. One way to do this is use as training data synthetic or actual examples of data from problems that the learning model is designed to solve. The learning model should preferentially be trained on real-world data, if possible, thus receiving a representative training set. When modeling buildings, however, data can only be gathered in real time; a single year-long data set takes a year to generate. Providing synthetic data produces its own sort of problems. When synthetic data is used, the learning model has a difficult time giving accurate answers to real-world data, as the real world includes examples that were not generated by the synthetic data generation procedure—the data is either overfitted (noise is misinterpreted as parameters) or underfitted (parameters are missed). This problem is so severe that “[i]t is quite common to invest days to months of time on hundreds of machines in order to solve even a single instance of the neural network training problem.” Goodfellow et al., “Deep Learning (Adaptive Computation and Machine Learning series)”, MIT Press, Nov. 18, 2016, p. 274. Another difficult to overcome problem is the large number of training sets required to generate usable solutions. As the number of parameters in a model rises, the amount of training data needed increases exponentially to achieve a state solution. The training data must also be representative of the data the model will actually encounter, or the results will be biased in a way that is difficult to ascertain. These models are also computationally intensive, such that models can require very expensive equipment to run, require very large amounts of time, and so on. This is made more difficult by the nature of real-world data-gathering. For example, as mentioned earlier, a single year-long data set for a building takes a year to accumulate.

To train a learning model using an optimizer, we start by using an optimizer to iteratively determine reasonable node starting values for a building simulation. Thousands of simulations may be run during the process of optimization, each with an input and output set. Each of the optimizer input and output sets is then used for training a learning model. As the simulation being discussed uses physics and a thorough understanding of the modeled structure to produce its results, the input and output from the optimizer simulations can be used as real-world data sets. After training, ideally, the learning model would now be able to produce outputs similar to that achieved by the optimizer-simulator optimization even when given unique problems. Even though the learning model can be considered trained, the optimizer-simulator, at a minimum, continues to be used to provide sanity checks on the results of the learning model, ensuring that the learning model continues to provide accurate answers. This prevents, among other things, over-and under-fitting engendered by, e.g., atypical scenarios. This also greatly reduces the computational power required to run any given model, as training sets are generated automatically, rather than using extra computing power; the trained learning model requires much less computational power and time to run than the optimizer, and so on.

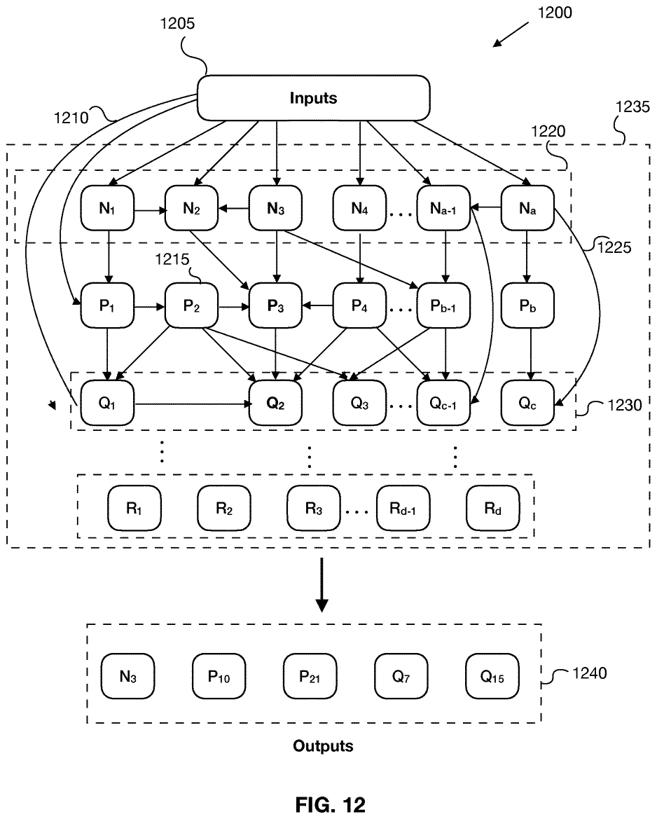

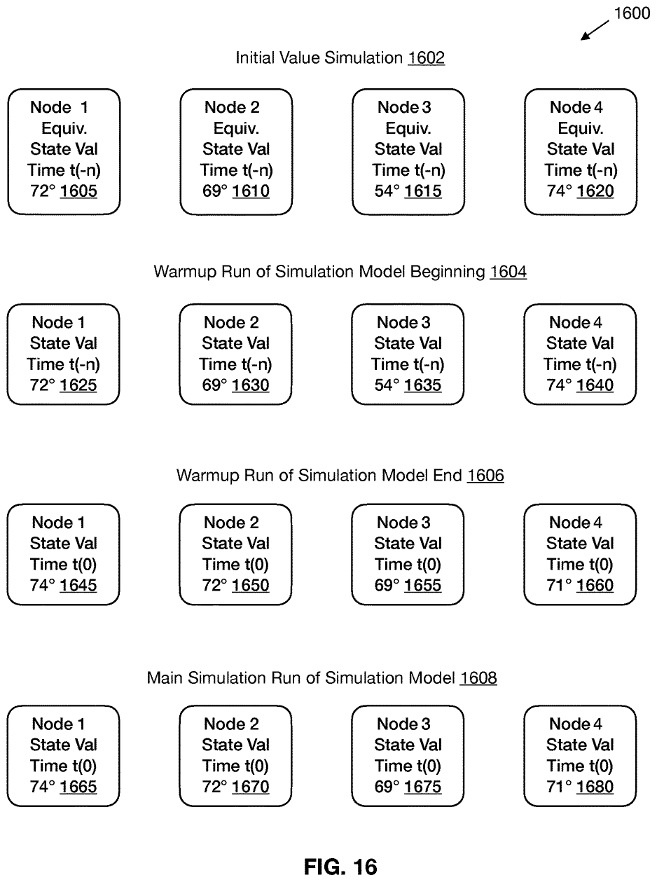

More specifically, in an embodiment, a state that can be measured (or at least determined) within a structure being modeled is chosen. In a building being modeled for HVAC control, this may be room temperature, which will be used in this embodiment. Rooms often have thermometers installed within them, and even when they do not, it is easy enough to measure temperature within a room over time. This chosen measurement (e.g., temperature) is then measured for some period of time in the rooms, giving a state-time curve. These temperature state time curves are then used as the “ground truth” for an initial value simulation. That is, the optimizer modifies beginning values within the simulator in an attempt to match the “ground truth” (the temperature time curves within rooms in the building) throughout the simulation. Before going further with our example, the makeup of the simulation model will be addressed. A digital twin simulation may break down the structure being modeled into nodes (described with more specificity with reference to FIGS. 12 and 16). These nodes may be portions of the building that separately carry state values (temperature, humidity, etc.), such as windows, ceilings, floors, studs, and the like. The nodes may represent even smaller chunks, such as layers of building portions. For example, an inner wall may be described by nodes that represent a layer of sheetrock with specific insulation values, a layer of insulation with its own values, studs, and another layer of sheetrock, and so on. An outside wall representation may have nodes that represent the outer material, such as brick, then insulation, then sheetrock, and so on. The digital twin simulator comprises these nodes, each with state values (e.g., temperature), connected. The point of the optimizer simulation and the state estimation simulation are to give these state values within the nodes reasonable values.

To determine how a building naturally warms up, ideally, the temperatures of rooms should be taken at the same time that the outside weather is being measured. This measured weather may then be used as input into the optimizer simulation models. The optimizer chooses temperature values (in this embodiment) for each of the nodes in the simulator. The simulation is then run. Running the simulation consists of the simulation applying the weather state inputs to the outside, and then letting the weather state (e.g., temperature) percolate through the structure for the simulation time. For the first time through, the optimizer may choose its node values at random, may use an earlier model node values, etc. At the end of the simulation, the nodes representing room temperature are checked against the desired room temperature, and the optimizer then chooses new values for the nodes in the simulation. The simulation is run multiple times, with the optimizer choosing new node values each time, until an optimal output is reached. This optimal output gives initial node values for a state estimation simulation to run, using the same simulator. At the end of the state estimation simulation, the simulation is considered to have reasonable temperatures within it, and so is ready to run a simulation.

At the same time this is happening, the learning model is being trained. The learning model may be thought of as running a backward version of the optimizer simulation: given the output desired (the desired temperature time curves for a structure) and outside state (weather) information it should return initial value digital twin simulation node values. That is, when the simulation is run with the learning model chosen node values (for the desired time), the simulation model will be considered to have a reasonable state—it will be warmed up. How does it do that? The learning model uses the reverse output of the optimizer simulation as input, and then produces reversed node state values as output. Specifically, the learning model uses as input the ground truth (in our current example, room temperature time value curves) and the weather time value curves that the optimizer uses for its simulation runs. Only, the learning model flips these time curves around backward. If the curves initially ran from time −300 to 0, then they will run from 0 to −300 producing output from 0 to time −300.

More specifically, the weather state time series (reversed) and the desired node value subset time series (reversed) are fed into the learning model as input. The learning model is set up so that it has the same number of output nodes that the simulator has nodes. These node values at the end of the learning model run are then checked against the starting values of the optimizer simulation run, e.g., the desired values. The cost (the difference between the two values) is then used to update the learning model using backpropagation or a similar learning method. This creates, e.g., a reverse building simulator, in that it is given the end values desired and produces the starting values that will arrive at those end values. With each training set, then the learning model gets slightly more accurate. As a single optimization cycle can produce thousands of training sets, the learning model may be able to be trained relatively quickly. Furthermore, as the data sets use not only actual data to be solved, but also actual solutions, the under-or over-fitting of training data is ameliorated.

This method is highly counterintuitive as to current uses of learning models. At the intuitive level cause and effect are reversed here. Simulators attempt to represent an evolution of cause-and-effect dynamics going forward. Going backward is impossible (in some situations) as one cannot rely on causality. As an example, if pool balls are in the starting triangle, with the white ball moving towards them, a simulator can be written to tell how the collisions and movement will unfold, with a reasonable amount of accuracy. But, if the balls are started in random locations, a simulator cannot be written that will tell the positions of the balls before the last shot. This is because they could have been in any number of positions, including the starting triangle formation, but there is no way to know which. It is easy to simulate forward, but cannot be simulated backwards within our lifetimes. One of the reasons for this is because of the Second Law of Thermodynamics. Entropy in a system always increases, until it reaches equilibrium. In some situations, once it has reached equilibrium, all information content about earlier system states has been erased. If that is true, you can't know anything about what the system looked like in the past with even the most clever simulator. For example, imagine two rods dipped into a single tank of room-temperature water. The rod on the left is hot, and the rod on the right is room-temperature. The rod on the left will bleed heat into the water (and the other rod). After a long enough wait, the two rods will be the same temperature. If someone walked into the room at that point, and were asked which rod was initially hot, they would have no way to know. All information about earlier states has been erased. A reverse simulator that would tell you which rod was hot could not be written. As another example, imagine a room-temperature pot of water on a stove. Over a ten minute period, the burner is turned on, for random spurts of time, to random heat settings, while a log of the burner actions is kept. At the end of the ten minutes, temperature of the water is at a certain value. At this point, the entries in the log are unrecoverable. Only the total amount of energy injected into the water can be determined. The exact sequence and strength of ‘signals’ in the log cannot be reconstructed. That information has been lost, as though the evolution of the water's thermodynamics acted as a lossy low-pass filter.

Here, in spite of all odds, running backward works anyway. The learning model sees the simulated structure's behavior over and over. So it can learn to leverage what information it has much more effectively than a pure backwards-physics simulator, which would be very hindered by these information-theory issues we've spelled out. In the absence of the ability to deterministically simulate, it can learn from past experience using the output from the optimizing simulator as training models.

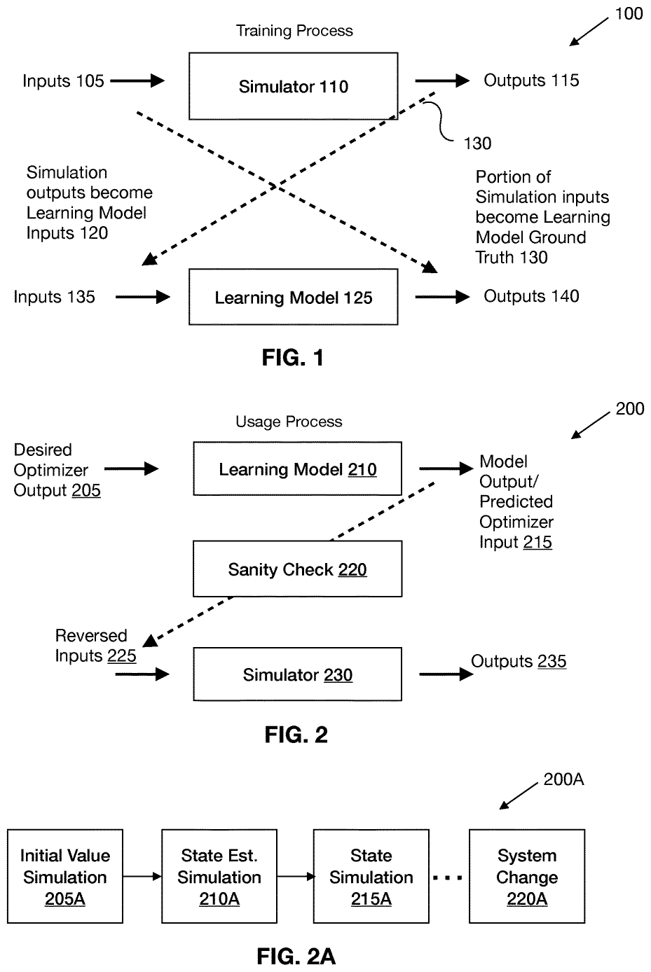

FIG. 1 at 100 discloses an overview of a training process to train a learning model. The learning model may be a supervised or unsupervised learning model. The learning model may use Linear Regression, logistic regression, decision trees, naive Bayes, KNN, etc. The learning model may be a neural network. The neural network may be a recurrent neural network, an artificial neural network, a convolutional neural network, etc.

To use a simulator 110 to develop training models for a Learning Model 125, the simulator 110 first runs the digital twin for a period of time—e.g., from a time prior to the simulation, such as t(−300) (representing 300 time units from where the actual simulation will take place), to t(0) (the time that the simulation starts). The digital twin may be a heterogenous node system. This heterogenous node system may be a heterogenous neural network. The inputs 105 may represent outside state that will be presented to the digital twin and used by the optimizer which affects a building over time, such as weather, humidity, vibration, magnetic, light, pressure, moisture, etc. This state then may propagate through the different layers, affecting the structure over the time of the simulation. The inputs may be state curves that run for the same amount of time as the simulation itself, so for our current example, it would be from t(−300) to t(0). The simulator 110 itself may model a digital twin of the building descried as nodes. These nodes may represent various building chunks. The constitution of the chunks depend on the specific implementation. In some cases, the chunks represent large scale structures in a building such as rooms; in some implementations, the chunks represent building portions such as walls, windows, floors, ceilings; in some representations, the chunks represent individual components of a building such as layers in a wall; i.e., a wall may be modeled as a specific type of drywall, followed by a specific type of insulation, followed by a specific layer of drywall, and so on. Some implementations may use both chunks representing large scale structures and individual components, etc. The nodes values may then be used to determine building thermodynamic behavior. The nodes are heterogenous as individual nodes may represent different building chunks, and so may have different properties. The properties may be state values. A “state” as used herein may be Air Temperature, Radiant Temperature, Atmospheric Pressure, Sound Pressure, Occupancy Amount, Indoor Air Quality, CO2 concentration, Light Intensity, or another state that can be measured and controlled. The properties may also be values associated with, e.g., the chunk of the building that the node represents, in some embodiments. Properties associated with equipment may also be used in the nodes, when appropriate, etc. For example, nodes may have properties such as heat capacity rates, efficiency, specific enthalpy, resistance, and so on. These properties may be used in equations to determine how state changes over time. An example of a node is shown with reference to FIG. 14.

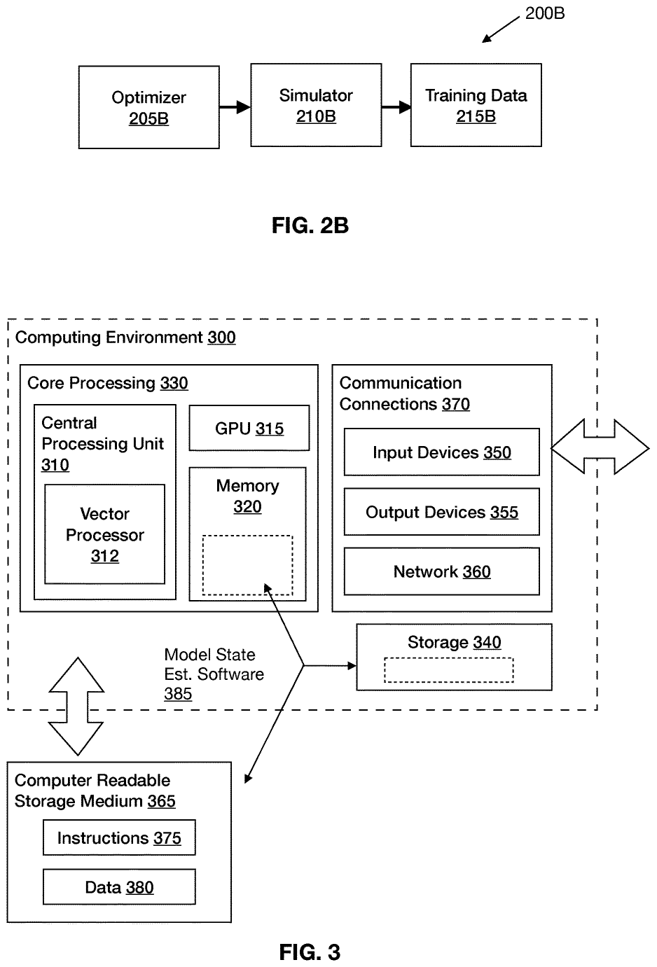

The inputs 105 may be presented to the location within the heterogenous node model that correspond to the areas that they will affect in the building. So, e.g., weather inputs may be presented to nodes representing outside walls, sun inputs may be presented to nodes representing windows facing toward the sun, and so on. The optimizer produces starting value node states as inputs 105 for the initial simulation starting time. After the simulation has been run with the optimizer starting values, output 115 is produced. The output is the state of the nodes in the simulation for the simulation time—state time curves. Selected node values, such as nodes that represent the the temperature inside rooms, may be measured against a set of ground truth state curves. The ground truth state curves may be actual temperatures measured over time in spaces that are represented by the simulator. For example, the temperature of rooms in a building may be measured over time, at the same time that the temperature and other state values of the location may also be measured. At the end of the simulation, the selected node values may be measured against a ground truth vector. These selected node values may be used in a cost function along with ground truth values. The cost function may measure an output (e.g., historical values of the room temperature) against the ground truth to produce a cost. The optimizer may then use the cost to improve the initial values, at which point the optimizer is rerun with new initial values for the nodes in the simulator. Selected node values from the outputs, along with state date is then run through the learning model as a new training example. This improvement may continue until a stopping state is reached. Once a stopping state is reached, that is, the simulator 110 (e.g., a heterogenous node system) has an optimized solution, a certain number of cycles have run; the model has run for a maximum time, etc., that solution may be used as starting values for a starting state estimation—a warmup run for the simulation. This is described in greater detail with reference to FIG. 2A.

When the simulator output 115 is used for learning model input, selected node values from the simulator—which may be for for the simulation time (e.g., time t(−300) to t(0))—are then reversed, such that they run from time t(0) to t(−300)—backwards. This reversed output 130 is then used as input 135 for the learning model 125. Similarly, a portion of the simulation inputs become the ground truth that the learning model outputs 140 are compared to. the output of the learning model and the inputs of the simulator he learning model may have a node that parallels each node (or most of the nodes) in the simulation 110. The simulation may be a heterogenous node simulation. The inputs used by the simulator model that have been similarly reversed 120, may also be used as input into the learning model 125. The learning model may be set up such that it outputs 140 state over time, such as value that represent inside temperature in rooms in a building. These state time curves are in reverse time order. The original output at the beginning of the model run (e.g., in our example, t(−300)), from the simulation model run is then used as ground truth. The ground truth is compared with the learning model output in a cost function to produce a cost. That cost may then be used for backpropagation within the learning model to improve the output of the model. According to the Wikipedia entry “Backpropagation”: “The back propagation algorithm works by computing the gradient of the loss function with respect to each weight by the chain rule, computing the gradient one layer at a time, iterating backward from the last layer to avoid redundant calculations of intermediate terms in the chain rule.” Backpropagation techniques are known by those of skill in the art. When the learning model is run with input and output from the optimizer simulation, the learning model simulation gets incrementally better at producing an outcome closer to that generated by the optimizer—it is trained.

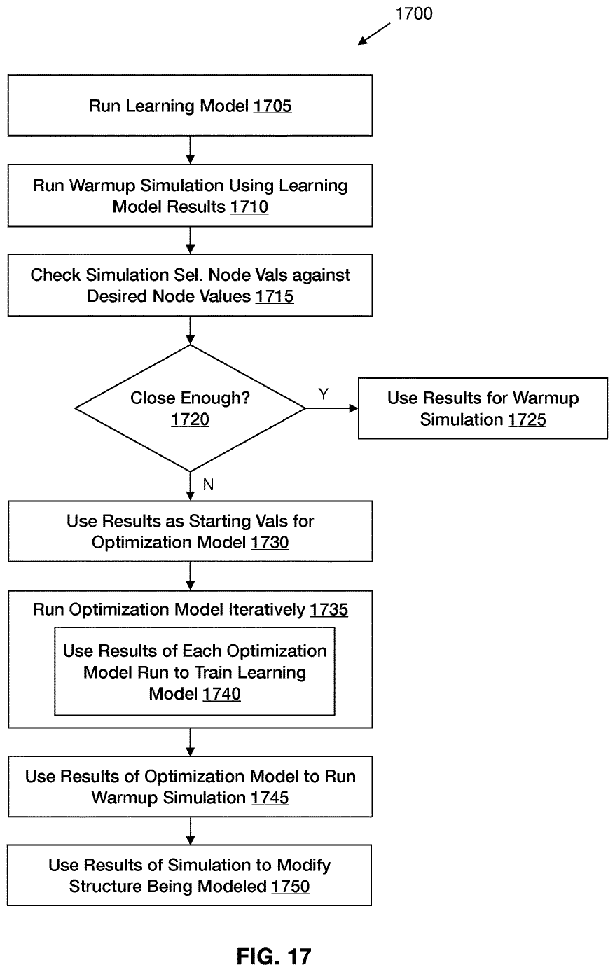

FIG. 2 at 200 discloses interaction between the learning model and the simulator when the learning model has been fully trained. The desired optimizer output of a subset of nodes 205 (e.g., room temperature nodes) at time t(0) to time t(−n), plus other state information, e.g., weather, also reversed from t(0) to t(−n), is used as input into the learning model 210. The learning model then outputs the value for all (or almost all) of the nodes at time t(−n) 215—the starting state for an initial value simulation 205A. These values may also be used as a sanity check 220 to ensure that the learning model is producing reasonable output, as described with reference to FIG. 17. Briefly, outputs 215 from the learning model 210 is reversed and used as input 225 into the simulator 230. Selected output 235 from the simulator 230 is checked against a ground truth, the desired output, to see how accurately the learning model is running.

FIG. 2A at 200A discloses a set of simulations that may be run to accurately determine starting values to warm up a digital twin. This gives more assurance that a simulation will be run with accurate starting values. The digital twin may then be simulated for a time to determine how the system represented by the digital twin will run in the future, with various inputs, with different values, etc. This simulation may then be used to determine how to run equipment, etc. within the system that the digital twin is simulating. First, an initial value simulation, as described with reference to FIGS. 1 and 2, is run. This produces initial state values for nodes in a simulation model. The model output 115, 215, which correspond to nodes in a simulation model, such as the simulator 110, is then used as initial values for nodes in a node simulation 210A that runs from a time prior to the simulation start—time t(−n), to the time the simulation starts—time t(0). This node simulation is run using the same node system that will be run for the state simulation 215A. Thus, the node simulation modifies the nodes in the state simulation such that they are at reasonable starting values. At time t(0)—the simulation start time—the nodes in the simulation model should have rational starting values in them such that a state simulation 215A (e.g., of a structure, etc.), may be run. Once the simulation has been run, output from the simulation may be used downstream to change the system being simulated 220A. For example, a digital twin simulation may comprise a floor of a building. Running the state simulation may optimize energy use within the floor of the building. Once the energy use is optimized, a device simulation may determine optimal (or close to optimal, or better than able to determine by hand) HVAC states for a period of time. These optimal HVAC states determined by the digital twin simulation may then be used to operate equipment within the building floor—causing a system change 220A. In some embodiments, the digital twin state simulation 215A may provide control sequences for specific pieces of equipment. These control sequences may then be used to run the specific pieces of equipment for the simulation period, i.e., from t(0) to t(n). For example, the digital twin simulation may provide a control sequence for a heater, specifying when it will turn on and turn off, providing a specific system change 220A. In some embodiments, the simulation may provide control sequences for periods shorter or longer than the simulation period, and with which the simulation output may be used. We disclose here methods and systems for the initial value simulation 205A that will determine the initial values for a node simulation 210A.

FIG. 2B at 200B discloses a relationship between an optimizer 205B and a simulator 210B. The optimizer 205B will determine values for some values of nodes in a simulator 210B such that, when optimized, desired values will be produced in a subset of the nodes at the end of the simulation. The optimizer may do this through an iterative machine learning system, as discussed elsewhere. The optimizer 205B may use, as ground truth, desired values for a selected set of nodes to determine optimal node values., This is described in greater detail with reference to FIG. 5 at 525. The optimizer may run the simulation multiple times with different starting values to determine an optimized set of starting values for use in a node simulation 210A. Each (or most or some) of the simulation runs with the initial values determined by the optimizer may be used as training data 215B for a learning model, eg., 125.

### II. Exemplary Computing Environment

FIG. 3 illustrates a generalized example of a suitable computing environment 300 in which described embodiments may be implemented. The computing environment 300 is not intended to suggest any limitation as to scope of use or functionality of the disclosure, as the present disclosure may be implemented in diverse general-purpose or special-purpose computing environments.

With reference to FIG. 3, the core processing is indicated by the core processing 330 box. The computing environment 300 includes at least one central processing unit 310 and memory 320. The central processing unit 310 executes computer-executable instructions and may be a real or a virtual processor. It may also comprise a vector processor 312, which allows same-length node strings to be processed rapidly. In a multi-processing system, multiple processing units execute computer-executable instructions to increase processing power and as such the vector processor 312, GPU 315, and CPU 310 can be running simultaneously. The memory 320 may be volatile memory (e.g., registers, cache, RAM), non-volatile memory (e.g., ROM, EEPROM, flash memory, etc.), or some combination of the two. The memory 320 stores software 385 implementing the described methods and systems using optimizers and/or learning models.

A computing environment may have additional features. For example, the computing environment 300 includes storage 340, one or more input devices 350, one or more output devices 355, one or more network connections (e.g., wired, wireless, etc.) 360 as well as other communication connections 370. An interconnection mechanism (not shown) such as a bus, controller, or network interconnects the components of the computing environment 300. Typically, operating system software (not shown) provides an operating environment for other software executing in the computing environment 300, and coordinates activities of the components of the computing environment 300. The computing system may also be distributed; running portions of the software on different CPUs.

The storage 340 may be removable or non-removable, and includes magnetic disks, magnetic tapes or cassettes, CD-ROMs, CD-RWs, DVDs, flash drives, or any other medium which can be used to store information and which can be accessed within the computing environment 300. The storage 340 stores instructions for the software, such as software 385 to implement systems and methods of warming up simulation models that rely on state being at a reasonable value.

The input device(s) 350 may be a device that allows a user or another device to communicate with the computing environment 300, such as a touch input device such as a keyboard, video camera, a microphone, mouse, pen, or trackball, a digital camera, a scanning device such as a digital camera with a scanner, touchscreen, joystick controller, a wii remote, or another device that provides input to the computing environment 300. For audio, the input device(s) 350 may be a sound card or similar device that accepts audio input in analog or digital form, or a CD-ROM reader that provides audio samples to the computing environment. The output device(s) 355 may be a display, a hardcopy producing output device such as a printer or plotter, a text-to speech voice-reader, speaker, CD-writer, or another device that provides output from the computing environment 300.

The communication connection(s) 370 enable communication over a communication medium to another computing entity. The communication medium conveys information such as computer-executable instructions, compressed graphics information, or other data in a modulated data signal. Communication connections 370 may comprise input devices 350, output devices 355, and input/output devices that allows a client device to communicate with another device over network 360. A communication device may include one or more wireless transceivers for performing wireless communication and/or one or more communication ports for performing wired communication. These connections may include network connections, which may be a wired or wireless network such as the Internet, an intranet, a LAN, a WAN, a cellular network or another type of network. It will be understood that network 360 may be a combination of multiple different kinds of wired or wireless networks. The network 360 may be a distributed network, with multiple computers, which might be building controllers, acting in tandem. A communication connection 370 may be a portable communications device such as a wireless handheld device, a personal electronic device, etc.

Computer-readable media are any available non-transient tangible media that can be accessed within a computing environment. By way of example, and not limitation, with the computing environment 300, computer-readable media include memory 320, storage 340, communication media, and combinations of any of the above. Computer readable storage medium 365 which may be used to store computer readable media comprises instructions 375 and data 380. Data Sources may be computing devices, such as general hardware platform servers configured to receive and transmit information over the communications connections 370. The computing environment 300 may be an electrical controller that is directly connected to various resources, such as HVAC resources, and which has CPU 310, a GPU 315, Memory 320, input devices 350, communication connections 370, and/or other features shown in the computing environment 300. The computing environment 300 may be a series of distributed computers. These distributed computers may comprise a series of connected electrical controllers.

Although the operations of some of the disclosed methods are described in a particular, sequential order for convenient presentation, it should be understood that this manner of description encompasses rearrangement, unless a particular ordering is required by specific language set forth below. For example, operations described sequentially can be rearranged or performed concurrently. Moreover, for the sake of simplicity, the attached figures may not show the various ways in which the disclosed methods, apparatus, and systems can be used in conjunction with other methods, apparatus, and systems. Additionally, the description sometimes uses terms like “determine,” “build,” and “identify” to describe the disclosed technology. These terms are high-level abstractions of the actual operations that are performed. The actual operations that correspond to these terms will vary depending on the particular implementation and are readily discernible by one of ordinary skill in the art.

Further, data produced from any of the disclosed methods can be created, updated, or stored on tangible computer-readable media (e.g., tangible computer-readable media, such as one or more CDs, volatile memory components (such as DRAM or SRAM), or nonvolatile memory components (such as hard drives) using a variety of different data structures or formats. Such data can be created or updated at a local computer or over a network (e.g., by a server computer), or stored and accessed in a cloud computing environment.

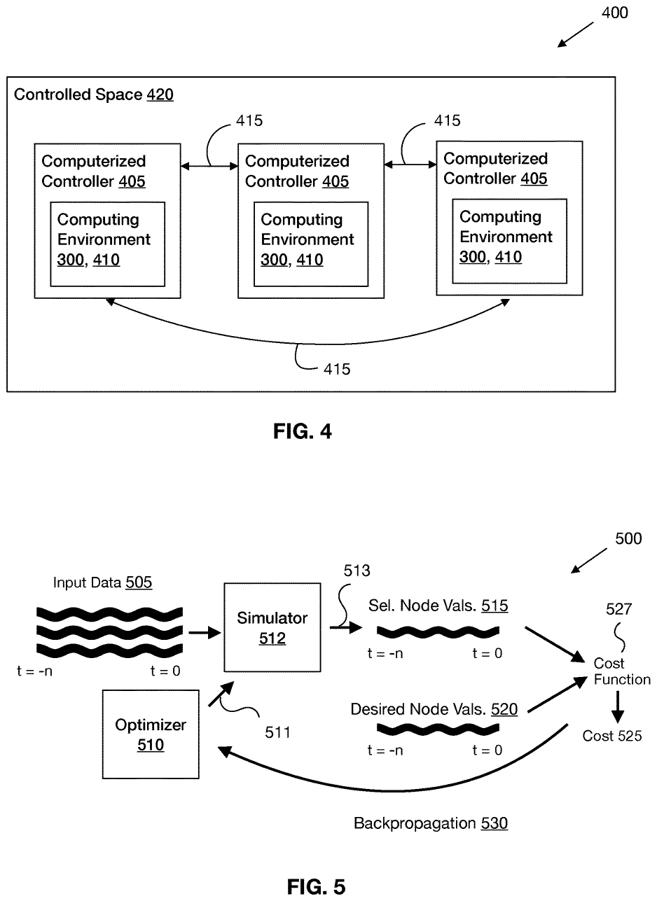

FIG. 4 depicts a distributed computing system 400 with which embodiments disclosed herein may be implemented. Two or more computerized controllers 405 may incorporate all or part of a computing environment 300, 410. These computerized controllers 405 may be connected 415 to each other using wired or wireless connections. The controllers may be within a controlled space 420. A controlled space 420 may be a space that has a resource, sensor, or other equipment that can modify or determine one or more states of the space, such as a sensor (to determine space state), a heater, an air conditioner (to modify temperature); a speaker (to modify noise), locks, lights, etc. A controlled space may be divided into zones, which might have separate constraint state curves. Controlled spaces might be, e.g., an automated building, a process control system, an HVAC system, an energy system, an irrigation system, a building irrigation system, etc. These computerized controllers 405 may comprise a distributed system that can run without using connections (such as internet connections) outside of the computing system 400 itself. This allows the system to run with low latency, and with other benefits of edge computing systems. The computerized controllers may run using an internal network with no outside network connection. This allows for a much more secure system much more invulnerable to outside attacks, such as viruses, ransomware, and just generally, computer security being breached in many other ways.

### III. Exemplary System Disclosure for Training a Simulator

FIG. 5 discloses an overview 500 of a training process to train a learning model by using an optimizer that does not require being trained itself to solve a problem; i.e., is untrained itself. The optimizer may be a machine learning algorithm, as known by those of skill in the art. The machine learning algorithm chooses initial state value node inputs. This initial choice may be random. These values are then used as initial state values in a simulation 110, 205A that runs from time t(0) to t(n). A desired value for the state values at time t(n) is known—the ground truth. The ground truth is compared with the values generated by the simulation at t(n) using a cost function which generates a cost. The cost is used by the machine learning algorithm to choose a new set of values that should generate values at the end of the simulation that are closer to the ground truth. When the simulator 110 is run, the outputs are used to train a learning model 125.

The simulator 110 may be a heterogenous neural network. This neural network may have activation functions in the nodes that perform separate calculations to determine weight values that are exiting the node. These separate calculations may be thermodynamic calculations that determines how state flows through the node. States may be characterized as weights entering and exiting nodes. An example of such a heterogenous neural network is described in patent application Ser. No. 17/009,713, “Neural Network Methods For Describing System Topologies”, filed Sep. 1, 2020 and incorporated herein by reference in its entirety. A typical neural network comprises inputs, outputs, and hidden layers connected by edges which have weights associated with them. The neural net sums the weights of all the incoming edges, applies a bias, and then uses an activation function to introduce non-linear effects, which basically squashes or expands the weigh/bias value into a useful range; often deciding whether the node will, in essence, fire, or not. This new value then becomes a weight used for connections to the next hidden layer of the network. The activation function does not do separate calculations, depending on the node, do not have physics equations associated with them, etc.

In some heterogenous neural networks, which might be used with embodiments described herein, the fundamentals of physics are utilized to model single components or pieces of equipment on a one-to-one basis with neural net nodes. When multiple components are linked to each other in a schematic diagram, a neural net is created that models the components as nodes. The values between the objects flow between the nodes as weights of connected edges. These neural nets may model not only the real complexities of systems but also their emergent behavior and the system semantics. Therefore, they bypass two major steps of the conventional AI modeling approaches: determining the shape of the neural net, and training the neural net from scratch. The nodes are arranged in order of an actual system (or set of equations) and because the nodes themselves comprise an equation or a series of equations that describe the function of their associated object, and certain relationships between them are determined by their location in the neural net. Therefore, a huge portion of training is no longer necessary, as the neural net itself comprises location information, behavior information, and interaction information between the different objects represented by the nodes. Further, the values held by nodes in the neural net at given times represent real-world behavior of the objects so represented. The neural net is no longer a black box but itself contains important information. This neural net structure also provides much deeper information about the systems and objects being described. Since the neural network is physics-and location-based, unlike the conventional AI structures, it is not limited to a specific model, but can run multiple models for the system that the neural network represents without requiring separate creation or training.

In some embodiments, the heterogenous neural network shapes the location of the nodes to tell something about the physical nature of the system. It may also place actual equations into the activation function. The weights that move between nodes may be equation variables. Different nodes may have unrelated activation functions, depending on the nature of the model being represented. In an exemplary embodiment, each activation function in a neural network may be different. For example, a pump could be represented in a neural network as a series of network nodes, some that represent efficiency, energy consumption, pressure, etc. The nodes will be placed such that one set of weights (variables) feeds into the next node (e.g., with an equation as its activation function) that uses those weights (variables). Now, two previous required steps, shaping the neural net and training the model may already be performed, at least to a certain portion. Using embodiments discussed here the neural net model need not be trained on information that is already known. It still needs to be trained on other information, such as is detailed here.

In some embodiments, the individual nodes represent physical representations of chunks of building material within a structure, equipment, etc. These individual nodes may hold parameter values that help define the physical representation. As such, when the neural net is run, the parameters helping define the physical representation can be tweaked to more accurately represent the given physical representation. This has the effect of pre-training the model with a qualitative set of guarantees, as the physics equations that describe objects being modeled are true, which saves having to find training sets and using huge amounts of computational time to run the training sets through the models to train them. A model does not need to be trained with information about the world that is already known. With objects connected in the neural net like they are connected in the real world, emergent behavior arises in the model that maps to the real world. This model behavior that is uncovered is otherwise too computationally complex to determine. Further, the nodes represent actual objects, not just black boxes. The behavior of the nodes themselves can be examined to determine behavior of the object, and can also be used to refine the understanding of the object behavior.

Conceptually, optimizing a structure simulation model comprises inserting some amount of some measurable state into a structure that may be modeled by the heterogenous network. This can be temperature, humidity, acoustic, vibration, magnetic, light, pressure, moisture, etc. This state then propagates through the different layers, affecting the structure. The input data 505 may be such state represented by a time curve. As an example, an outside node in the heterogenous network may be associated with a time heat curve T. The curve value at time t(−n) is injected into one or more outside nodes. This temperature is propagated through the building, e.g., through the represented layers (brick, insulation, drywall, etc.) by modifying values of the nodes of the simulation neural nets using physics representation. The outside of the building (say, brick), has its temperature modified by the outside node and known aspects of how heat transfers through brick as found in the brick node. The brick then heats up the next layer, perhaps insulation. This continues throughout the building until an inside node is reached. This may represent the space inside a room. At inside nodes, other functions can be applied, such as those that represent lighting and people (warmth) within the zone of the node. State information continues to propagate until another outside layer is reached, with individual node parameter values representing the heating present in the building at time T₀. In some embodiments, each outer surface has its own time temperature curve. In some embodiments a structure is deconstructed into smaller subsystems, (or zones) so rather than propagating temperature through the entire structure, only a portion of the structure is affected by a given input.

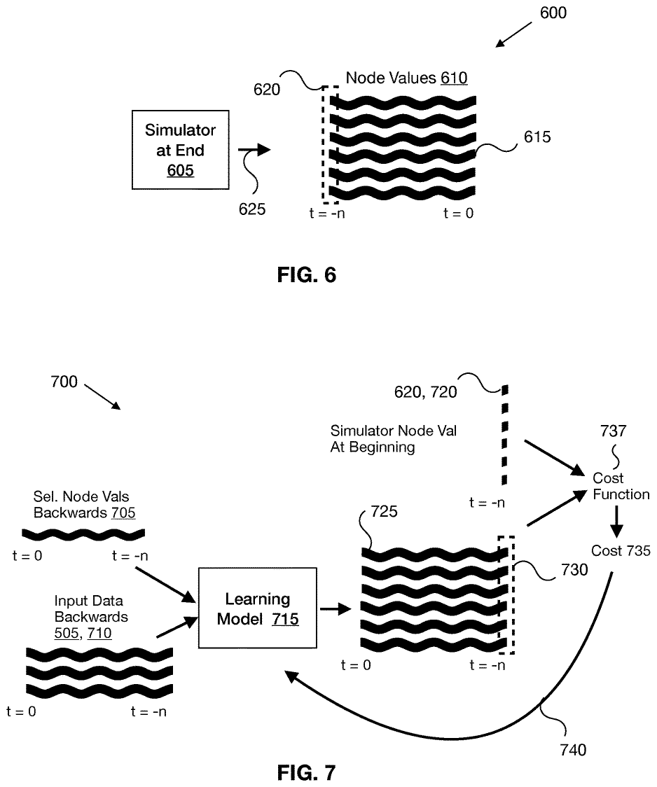

The optimizer 510 chooses the initial values of state and then passes them as optimizer output 511 to the simulation. To choose the initial values, the optimizer uses machine learning algorithms that do not require training, or that are already trained. The optimizer runs iteratively, ideally choosing better initial node values with the iterations. The simulator runs for each (or some) iterations with the starting values chosen by the optimizer. As output 513, nodes in the simulator produce node values for the length of the simulation, as described in FIG. 6. Among those nodes, a subset is output as selected node values 515. These are state/time curve(s) that run from the start time to the end time of the simulation. In some embodiments these selected node values are the temperatures of rooms within a structure. Other states may be used, as well. Ground truth for the machine learning algorithm may be a state/time curve of desired node values 520. These desired node values may be taken from an earlier simulation, may be approximated, may be historical values, etc. The cost function for the machine learning algorithm uses the selected node values 515 and desired node values 520 to run a cost function 527 and determine a cost 525—the difference between the predicted selected node values 515 from the simulator 512 and the desired node values (the ground truth) 520.

A “cost function,” generally, compares the output of a simulation model with the ground truth—a time curve that represents the answer the model is attempting to match. This gives us the cost—the difference between the simulated truth curve values and the expected values (the ground truth). The cost function may use a least squares function, a Mean Error (ME), Mean Squared Error (MSE), Mean Absolute Error (MAE), a Categorical Cross Entropy Cost Function, a Binary Cross Entropy Cost Function, and so on, to arrive at the answer. In some implementations, the cost function is a loss function. In some implementations, the cost function is a threshold, which may be a single number that indicates the simulated truth curve is close enough to the ground truth. In other implementations, the cost function may be a slope. The slope may also indicate that the simulated truth curve and the ground truth are of sufficient closeness. When a cost function is used, it may be time variant. It also may be linked to factors such as user preference, or changes in the physical model. The cost function applied to the optimizer may comprise models of any one or more of the following: energy use, primary energy use, energy monetary cost, human comfort, the safety of building or building contents, the durability of building or building contents, microorganism growth potential, system equipment durability, system equipment longevity, environmental impact, and/or energy use CO2 potential, or something else. The cost function may utilize a discount function based on discounted future value of a cost.

In some implementations, a goal function is used to determine if the cost is such that the operation can stop. Some implementations also include a stop state; a secondary state, such as another quit option, such as quit if the optimizer 510 or the simulator 512 has run for a certain amount of time, or has run for a number of cycles. If indicated (by the stop state, the goal function, or the cost function), the machine learning algorithm continues. In some implementations, information from output of the simulation, such as the simulation prediction selected node values and the cost function are used to update initial state values by the optimizer 510. This value updating may be implemented at least partially by back propagation 530. The optimizer 510, after updating, then chooses new state node values for the next round of simulation. The optimizer 510-simulation 512 cycle may run until a stop state (defined by some combination of one or more of the cost function, time the optimizer has run, time the optimizer and simulator has run, time the entire program has run, number of cycles the program has run, number of training runs taken by the learning model, etc.) is reached.

FIG. 6 at 600 discloses some outputs of the simulation 512, 605 that has starting values generated by the optimizer 510. The simulator 512, 605 outputs as simulator outputs 625 time state curves 615 for all (or some selected amount) of the nodes 610 in the heterogenous node system 210B. These time state curves run for the length of the simulation, or some period within the simulation. The initial simulator node values, that is, the node values at the start of the simulation (t=(−n)) are then saved to be used as a training example for the learning model. In some cases, these node values at the start of the simulation will also be used as input into a node simulation 210A to warmup a model to produce a reasonable state simulation 215A.

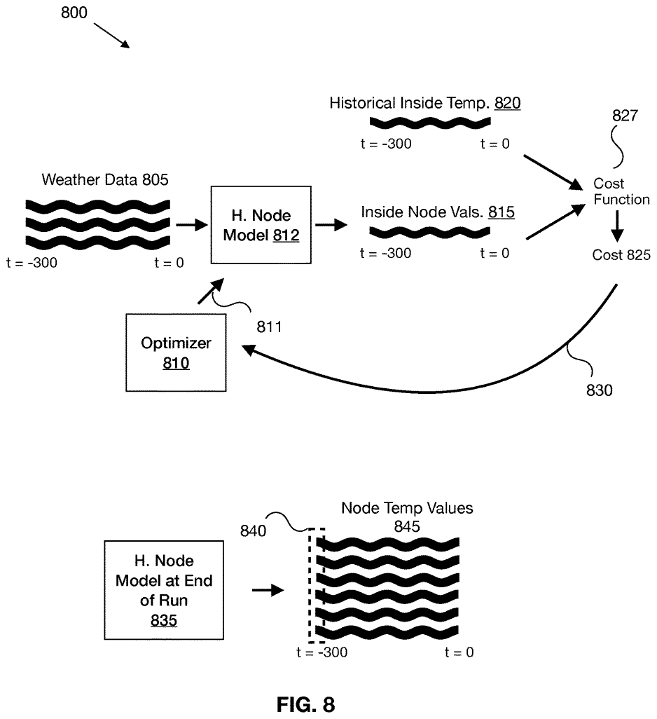

FIG. 7 at 700 discloses using simulator model output as learning model input. The selected node values output 515 from the simulator 512 are reversed 705, such that the state/time curve is flipped backwards; rather than being from t(−n) to t(0) it will now be from t(0) to t(−n). This produces reversed selected node values. Conceptually, when run, the simulation can be thought of as running backwards in time. Similarly, the input data 505 into the simulator is also reversed 710, producing reversed simulator input. It is then used as input into the learning model 715. This learning model 715 may be a type of neural network that requires training, such as, without limitation, a recurrent neural network, a convolution neural network, a feed forward neural network, a multilayer perceptron, a long/short term memory (LSTM), a gated recurrent unit (GRU), an auto encoder (AE), a variational AE (VAE), a denoising AE (DAE), a deep convolutional network, (DCN), and so on. This learning model should be set up to have the same output nodes as all (or essentially all, or some) of the nodes in the node system 210B used in the simulator; as such, the learning model will output a state/time curve for those nodes 725. The ground truth for this simulation are the starting node values 620, 720 for a given optimizer-simulator run. The learning model outputs a state/time curve for the nodes, with the state/time curve in reverse order. The last value for the nodes 730 (e.g., at time t(−n)), is then compared with the starting value 620, 720 of the nodes from the simulator 600 run, in a learning model cost function 737, to arrive at a a cost 735. The cost value is then used in backpropagation 740 to improve the Learning Model 715 inner node values. Backpropagation propagates the cost through the neural network, modifying the weights such that the ones with higher error rates have their weights lowered, while the nodes with lower error rates have their weights raised.

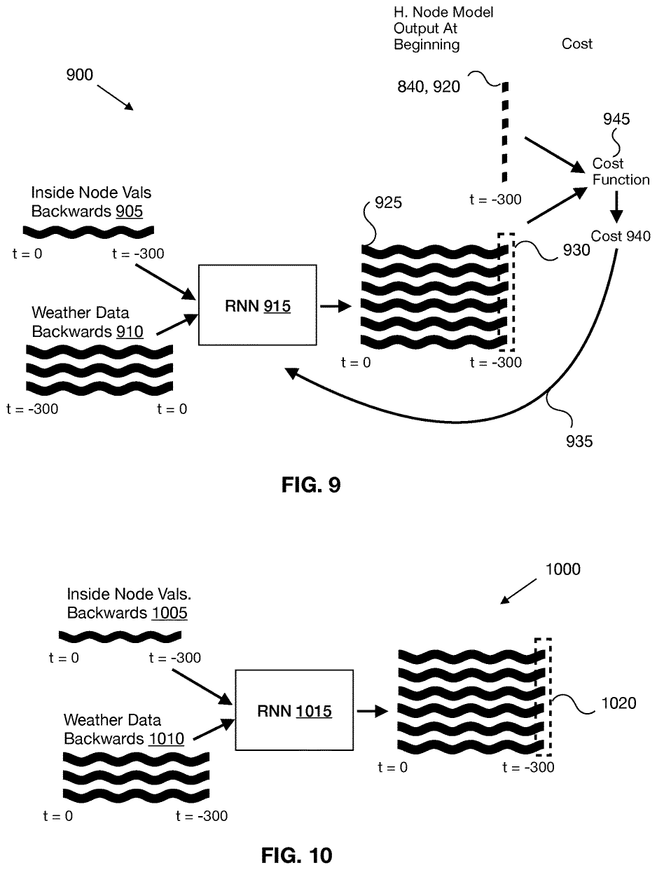

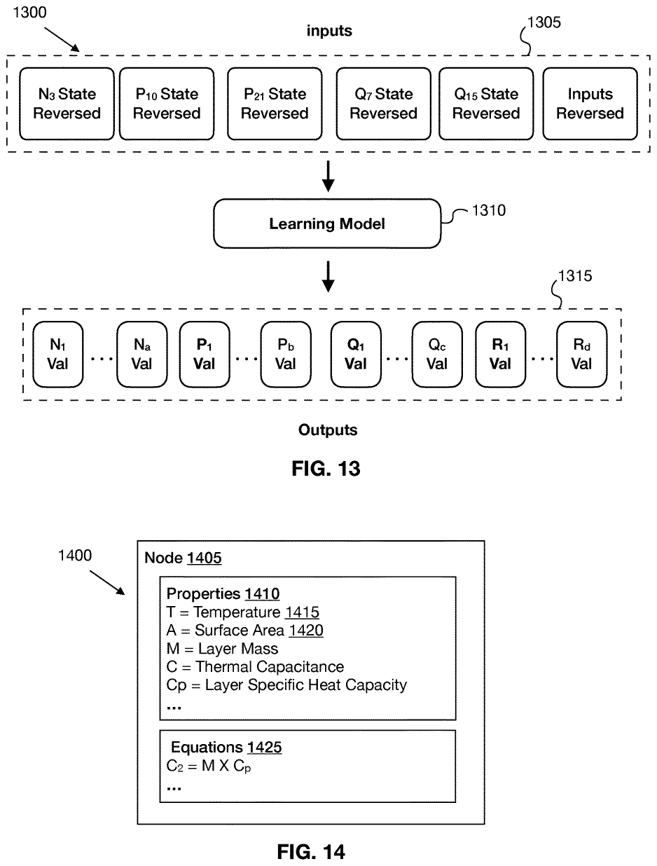

Turning now to FIGS. 8 and 9, FIG. 8 illustrates an example 800 of a heterogenous neural network model optimizer 810 used to both produce starting values that will be used to warmup a building simulator, and to train an RNN to produce the same or similar starting results. An RNN is a Recurrent Neural Network. Recurrent Neural Networks were developed in the 1980's and are well known to those of skill in the art. Briefly, RNNs have loops from a node to itself, between nodes, etc., which allow the RNN to, essentially, remember information, and so make decisions based on previous input. FIG. 9 illustrates an example of training an RNN Learning Model 915 using input values taken from optimizer input and output values. (105) Initially, the temperature inside rooms in a building that is to be modeled for a period of time, and the weather data (weather for the same period of time associated with the building location) is determined. An optimizer 810 determines starting temperature values as optimizer output 811 for the nodes in the heterogenous node model 812. The heterogenous node model 812 is then run, with weather data 805 (which may be temperature data) used as input in places equivalent to places in the heterogenous node model that weather values would enter an actual building, such as nodes representing outside walls. The heat values from the weather data 805 are propagated throughout the heterogenous model of the building 812 for the simulation run time—in this case, from t(−300) to t(0). The heterogenous node model 812 returns the inside node value temperature 815 (for the simulation time) of rooms as represented in the simulation. At the end of the simulation 835 the inside node room temperature values 815 are then compared to the historical inside temperature state/time curves 820 for the length of the simulation using a cost function 827 to determine a cost 825. The entire time curve (or a large section of it) is generally used, because if only the temperature for the last time value is used, for example, the optimizer solution may not represent a rational temperature warmup. For example, the model could represent temperature shooting up at the last time value, which would not give an accurate first time temperature, as is desired. In some embodiments, a portion of the time curve is used for the inside node values 815. The cost function uses the chosen inside node values 815 to measure against the ground truth historical node temperatures 820 using a cost function 827 to produce a cost 825. The cost 825 is then used by the optimizer 810 to modify the starting node temperature values that will then be used as starting node values within the heterogenous node system. This set of actions is repeated 830 until a stopping state is reached, to produce an optimized set of inside temperature node values for all (or most) of the nodes within the heterogenous node model 812. When the heterogenous node model 812 is run, the temperature value of its nodes 845 (which may have many state values such as temperature, humidity, etc.), are reported for the simulation time, e.g., from time t(0) to time t(−300). In some embodiments, the heterogeneous node system may report node values through a model run, rather than at the end. This is described in more detail with reference to FIGS. 12 and 13. The initial value of the nodes 840 of the heterogenous node model at the end of the simulation 835, that is, at time t(−300), will be used as the ground truth for training the RNN. The optimizer 810—heterogeneous node model 812 cycle is run until a stopping state is reached. When time starting values for a starting state simulation estimation simulation are determined, therefore, many training examples for the RNN are generated.

FIG. 9 illustrates an example 900 of training an RNN Learning Model 915 using optimizer 810—heterogenous node model 812 results. The RNN should have, as output, nodes that correspond to nodes in the optimizer model. This is discussed in greater detail with reference to FIGS. 12 and 13. The RNN, therefore, may produce beginning node values that can be used for a starting state simulation estimation simulation, e.g., 210A. The inside node values 815 (the temperature inside the rooms) from the heterogenous node model 812 are rewritten reversed, e.g., backward 905 to run from t(0) to t(−300). The weather data 805 is also rewritten backwards 910. These backwards inside node values 905 and backwards weather data 910 are then fed as input into the RNN, which outputs a value 925 for each (or most) of the nodes found in the heterogenous node model. The RNN 915 returns the last value 930 for the nodes in the RNN (in our example at time(t−300)), which should be understood as the first value, e.g., t(−300), when the temperature curves are again reversed to forward in time.

These output values 930 are then used in a cost function 945 with the heterogenous node model node temperature values 840, 920 that are sampled at the beginning of the warmup period (e.g., t(−300)) to determine a cost 940. This cost 940 is then used for backpropagation 935 to train the network. This process, where the RNN is trained using the input and output from an optimizer, is continued until the RNN is considered trained. Backpropagation, short for “backward propagation of errors” is widely used to incrementally train neural networks. According to the Wikipedia entry “Backpropagation”: “The back propagation algorithm works by computing the gradient of the loss function with respect to each weight by the chain rule, computing the gradient one layer at a time, iterating backward from the last layer to avoid redundant calculations of intermediate terms in the chain rule.”

FIG. 10 at 1000 discloses running a RNN 1015 after it has been trained. Desired reversed backward inside node values 1005 represented as state time curve for the length of the starting state simulation estimation simulation, in this case t(0) to t(−300) (“t” is for “time), and the reversed weather data 1010 are used as input into the RNN 1015. The RNN then outputs the last values for the RNN 1020 (e.g., at t(−300)), which are the initial values that will be input into a starting state simulation estimation simulation 210A to warm the model up.

### IV. Exemplary Methods for Training Simulators

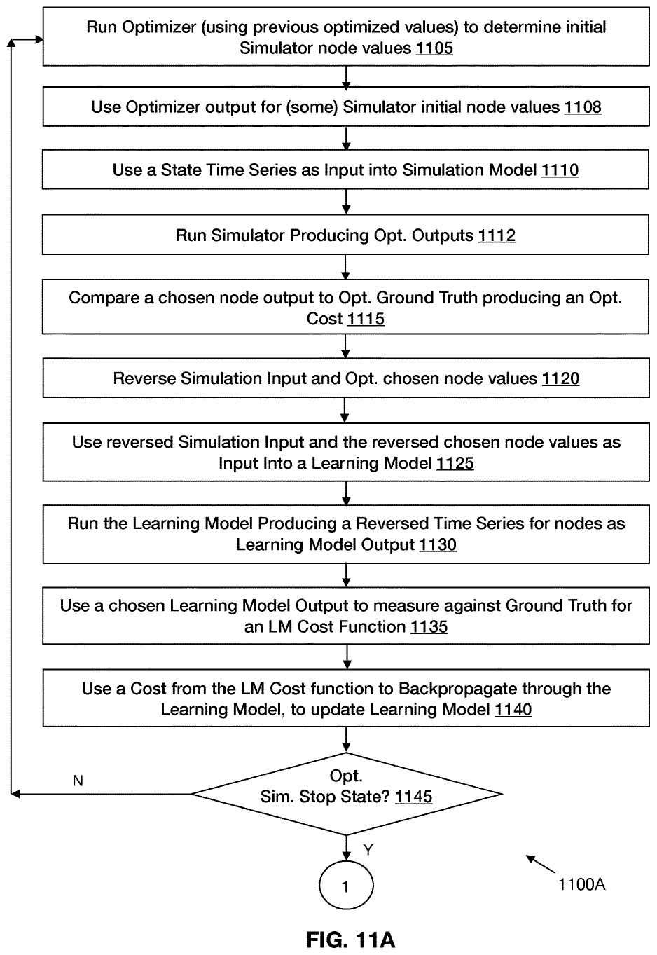

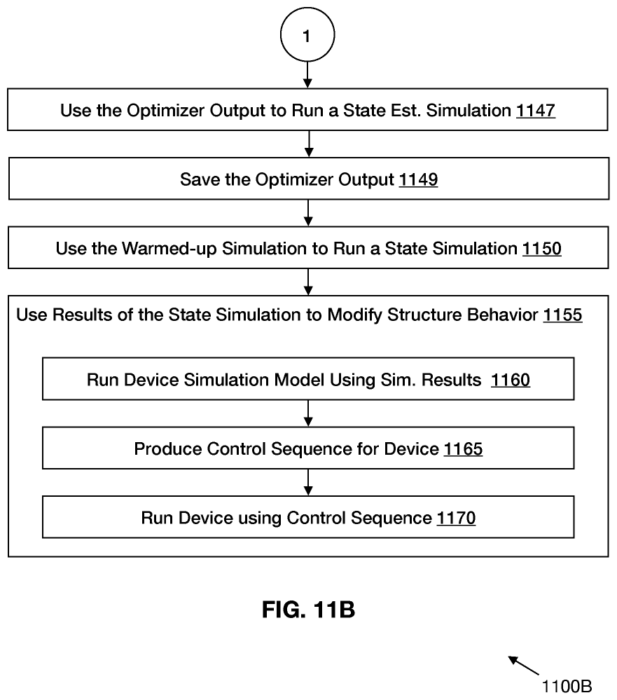

FIG. 11A at 1100A and FIG. 11B at 1100B is a flow diagram which describes how a simulator may be trained, and describes how the trained output may be used. The operations of method 1100A, 1100B presented below are intended to be illustrative. In some embodiments, method 1100A, 1100B may be accomplished with one or more additional operations not described, and/or without one or more of the operations discussed. Additionally, the order in which the operations of method 1100A, 1100B are illustrated in FIGS. 11A and 11B and described below is not intended to be limiting.

In some embodiments, the computer-enabled method 1100A, 1100B may be implemented in one or more processing devices (e.g., a digital processor, an analog processor, a digital circuit designed to process information, an analog circuit designed to process information, a state machine, and/or other mechanisms for electronically processing information, a multiprocess system, etc.). The one or more processing devices may include one or more devices executing some or all of the operations of method 1100A, 1100B in response to instructions stored electronically on an electronic storage medium. The one or more processing devices may include one or more devices configured through hardware, firmware, and/or software to be specifically designed for execution of one or more of the operations of method 1100A, 1100B. 10.

At operation 1105, an optimizer is run to determine (some) initial node values for a simulator that simulates a structure, a process, etc. These node values may be, for multiple nodes, an initial state value, such as temperature, etc. These nodes in the simulator may have physics equations associated with them, as described, e.g., with reference to FIG. 14 and the surrounding text. An optimizer is described with reference to FIG. 1 at 110, FIG. 2B, FIG. 5 at 510 and FIG. 8 at 810. These physics equations may model how state (such as the input time series) moves through the nodes through time. At operation 1108, the optimizer output (e.g., 811) is used as starting node values for some or all of the simulator initial node values. At operation 1110, an input time series is used as input into the simulator. In some embodiments, many time series may be used as input. FIG. 5 at 505 and FIG. 8 at 805 show examples of input time series. At operation 1112, the simulator is run. At the end of the simulation (e.g., the end of the input time series), optimizer output is produced. This optimizer output may consist partially of chosen node output values. FIG. 5 at 515, FIG. 6 at 610, and FIG. 8 at 820 show aspects of simulator output. FIG. 12 describes more details of. At operation 1115, the chosen node output values are compared with a ground truth using a cost function, producing a optimization cost. At operation 1120, the optimizer simulation output is reversed. Examples of this are shown with reference to FIG. 7 at 705, and FIG. 9 at 905. Also at operation 1120, the optimizer input is reversed. Examples of this are shown with reference to FIG. 7 at 710, and FIG. 9 at 910. At operation 1125, the reversed optimizer simulation output and at least a portion of the reversed optimizer simulation input is used as input into a learning model. Examples of this are shown with reference to FIG. 7 at 705 and 710, and FIG. 9 at 905 and 910.

At operation 1130, the learning model is run, producing a reversed time series—from t(0) to t(−n)—as learning model output which map to a portion (or all) nodes used in the simulation. At operation 1135, the learning model output values at a time t(−n) is used as input into a cost function, e.g., 737, 945, producing a cost 735, 940. The optimizer simulation output beginning node values (620, 720) is used as ground truth for the cost function 737. This is explained in greater detail with reference to FIG. 7 and the surrounding text. The Learning Model value of its nodes at its end time (the actual beginning time) is compared to the Physical Model output at the beginning time to determine a cost 735—that is, a difference between the ideal output (the ground truth) and the actual Learning Model values. An example of this is shown with reference to FIG. 7 at 720, 730, 735, and 737. At operation 1140, the computed cost is then used to perform backpropagation of the Learning Model, further training the Learning Model. At decision point 1145 it is determined if the simulation has run to a stopping state. This stopping state may be that the cost from the cost function of the optimization simulation output (see 1115) is sufficiently small to indicate that the initial warmup values for the simulation model has been optimized. Other stopping states may also be used, such as number of iterations of the simulator, amount of time that the model has been run in toto, etc. If not at the stop state, then the process repeats at operation 1105. If determined to be at the stop state, then at operation 1147 the optimizer output (the starting state values for a simulation) is used to run a starting state simulation estimation simulation. The optimizer output, as shown with reference to FIG. 6 and FIG. 8, are starting node state values for a starting state simulation estimation simulation. The starting state simulation estimation simulation may be run for the times that the initial value simulation was initially run, e.g., from a time prior to the simulation (t=−n) to the time the simulation starts (t=0).

At operation 1149, the optimizer output is saved. At operation 1150, a state simulation is run using the warmed-up simulation. Specifically, the state simulation is run from time t=0 forward for an appropriate time, such as t(m), where m equals some positive number. The state simulation may be an extension of the starting state simulation estimation simulation run. At operation 1155, after the state simulation is run, results of the state simulation may be used to modify behavior of the structure that the simulation is modeling. One way that the structure behavior may be modified is by using simulation output to eventually direct device behavior. The structure may contain various devices that can be controlled. These devices may be scientific instruments, HVAC equipment, and so on. These devices may be modeled in a separate device simulation 1160. The results of this device simulation may be control sequences for the devices that were modeled. The simulation may optimize the device behavior to achieve certain results. For example, a building simulation may seek to optimize energy usage. As such, devices such as air conditioners, moveable vents, heaters, boilers, etc., may be modeled within a building structure. At operation 1165, the state simulation may produce outputs that may modify the behavior of the structure that is being modeled by the simulator, such as control sequences. At operation 1170, these control sequences may then be used to run at least one device. For example, an air conditioner may be run using the control sequence generated by the state simulation.

FIG. 12 at 1200 discloses an exemplary simulation model 1235 with exemplary nodes with which embodiments disclosed herein may be implemented. When a simulation model is run, input data 505, 1205 is fed into certain nodes. The input data for the optimizer run of the state simulation is described in greater depth with reference to FIG. 5. In some implementations, the nodes may be arranged into levels. For example, nodes in a first level 1220 are labeled N₁, through Nₐ. Not all nodes may be shown, as indicated by the ellipsis. Below that level is a level whose nodes are labeled P₁, through Pₐ. Another level 1230 holds nodes Q₁-Q_{c}. Some implementations may not have nodes arranged into levels. Input data 1205 (e.g. data 505 such as weather data) may be fed into nodes in a first level 1220, and nodes in a different level 1210. Nodes on one level may feed information into nodes other than the level next to them. For example, node Nₐ (in level N) may feed information 1225 into node Q_{c} (in level Q), skipping level P. There may also be other node levels, such as R, which does not have inputs and outputs shown, for clarity in the drawing. Nodes in one level may not necessarily send information to other nodes at the next lower level, as shown with reference to P₂ 1215. The entire set of nodes for the optimizer in the current example may be described as N₁-Nₐ, P₁-P_{b}, Q₁,-Q_{c}, R₁-R_{d}.

The model outputs, e.g. selected node values 515, may not be a specific layer, but rather may be a collection of nodes 1240 deep with the model. In the example shown, N₃ (the third node from the left on row N), P₁₀, P₂₁, Q₇, and Q₁₅ may all be considered selected node values. Other output nodes may not be shown. There may be a reason for this specific set of nodes being considered output nodes. For example, they may represent a state that has an actual measurement in a corresponding real world structure. For example, selected nodes may represent the inside of a room, and there may be a node value that holds a temperature that represents the temperature of the room represented by the node. The selected nodes may then be the nodes representing the inside of rooms in a building, with the selected node values being the temperature of the selected nodes.

FIG. 13 at 1300 discloses exemplary learning model and outputs with which embodiments disclosed herein may be implemented. Inputs 1305 may be the output of a selected set of nodes 1240 from the simulation. A state output (such as temperature) of these nodes is then reversed 1305 and then used as input 1310 into a learning model. In the illustrative example the learning model has output 1315 that includes a value (or values) associated with the nodes in the simulation model 1235 N₁-Nₐ, P₁-Pₐ, Q₁,-Qₐ, and R₁-Rₐ. Thus, the nodes of the simulation model 1235 have counterparts as the output 1315 of the learning model. In some embodiments, a portion of the nodes in an output model have counterparts as outputs in the learning model. The nodes may have multiple properties associated with them. In such a case a value or values of specific property information within the nodes may be recorded for the length of the simulation (t(0)-t(n)) and then be used as the output 1240.

FIG. 14 at 1400 discloses an exemplary node. Properties 1410 are properties of the object or building chunk being represented by the node. For example, a node 1405 may have temperature 1415 as a property 1410 that changes through a simulation. Other properties, such as, e.g., surface area 1420 may remain static. In some embodiments, nodes may include equations 1425 in a system that are to be solved. These equations may have both variables that are represented in the neural net as edges with weights, and variables that are properties 1410 of the node itself.

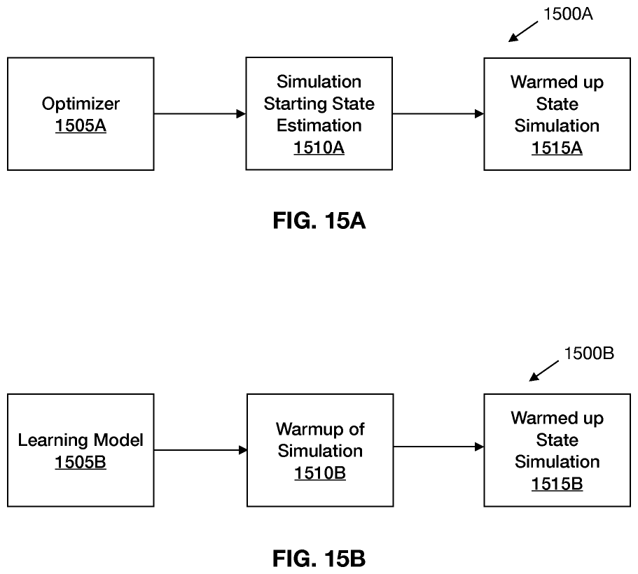

With reference to FIG. 15A, a work flow 1500A is shown that may be used to estimate starting state for a state simulation. An optimizer 1505A is run, which after optimization produces values that will be used as initial node values within a simulation 1510A that will be used for state estimation. There may be a one-to-one correspondence between values in the optimizer 1505A and nodes in the simulation (e.g., warmup) that will be used for the starting state estimation function. The nodes within the simulation may have one value that is determined by the optimizer or several values that are determined by the optimizer. This startup state estimation simulation 1510A may run from a prior time (−t) to the starting time of a simulation (0). When the simulation is at time (0), then the same simulation model with reasonable inner node values may be run 1515A for a time into the future.

With reference to FIG. 15B, a work flow is shown 1500B that may be used to warmup a state simulation using a trained learning model—estimating starting state for a state simulation. A learning model 1505B is run, which then produces values that will be used as initial node values within a simulation 1510B that will be used for starting state estimation. There may be a one-to-one correspondence between values in the learning model output and nodes in the simulation that will be used for the starting state estimation function. The nodes within the simulation may have one value that is modified by the learning model output or several values. This starting state simulation estimation simulation may run from a prior time (−t) to the starting time of a simulation (0). When the starting state estimation simulation is at time (0), then the same simulation model 1515B may be run for a time into the future with the warmed-up node values provided by the starting state estimation simulation 1510B.

FIG. 16 at 1600 discloses node values in initial value simulations 1602, starting state estimation runs of a simulation model 1604, 1606, and a simulation run of a simulation model 1608. In the abbreviated model shown (for brevity), an initial value simulation 1602 has four nodes, as does a simulation model. These four nodes, 1605, 1610, 1615, and 1620, at the end of the initial value simulation, be it an optimizer or a learning model, will produce state values that will be used for the initial value for corresponding starting state estimation run of a simulation model 1604, 1606 that will be used to simulate the structure, process, etc. For example, the node 1 equivalent at the end of the initial value simulation 1605, e.g., time t(−n), has the temperature state values of 72°. This temperature state value is then transferred over to the simulation that is being prepared for a starting state estimation run 1604—node 1 receives the temperature state 72°. This is true for the rest of the nodes in this example. ; e.g., node 2 1630 receives the temperature 69° from node 2 1610 of the initial value simulation 1602, node 3 1635 receives the node equivalent 54° from the node 3 equivalent 1615, and node 4 1640 receives the temperature 74° from the node 4 equivalent 1620. In some embodiments, the state (e.g., the temperature in this model) is transferred over with no changes. In some embodiments, the state from the node equivalent of the initial value simulation 1602 undergoes a transformation before being transferred over to the beginning of the starting state estimation run 1604. Once the starting state estimation run of the simulation 1604 has been seeded with node values from the initial value simulation run 1602, it is then run for some time period, which changes the state values, as can be seen for the node values at the end of the starting state estimation simulation 1606. At starting state estimation simulation end, there may be a check to determine if the simulation has been sufficiently warmed up—that is, if the internal node values are at a reasonable state (or at reasonable states) to begin the actual simulation. If there is such a check, and the model is determined sufficiently warmed-up, or if no check, directly after the starting state estimation run 1604, then the main simulation run 1608 is started. At the start of the main simulation run of the simulation model 1608, the simulation nodes 1665, 1670, 1675, 1680 may be the same nodes 1645, 1650, 1655, 1660 as those of the starting state estimation simulation 1606, in which case they will automatically have the same state values that were produced at the end of the starting state estimation run 1606. For example node 1 at time t(0) 1665 with have the value 74°, which is the same value as node 1 1645 at the end of the starting state estimation run. In some embodiments, the starting state estimation end values may be transferred to a different simulation. In general, the node values at the start of the main simulation run 1608 of the simulation model may have the values as the corresponding nodes of the starting state estimation run of the simulation at the end of the starting state estimation simulation 1606.

FIG. 17 at 1700 discloses running a trained learning model using a sanity check. At operation 1705 the learning model is run, using as input the desired selected node values backwards and state values backwards, as discussed in FIG. 9. At operation 1710, a starting state estimation simulation, e.g., 1510B, is run using the node values provided by the learning model. At operation 1715, selected node values from the simulation and the ground truth (e.g., historical node values, etc.) are used in a cost function to determine a cost measuring the distance between the two sets of values. At decision point 1720 it is determined if the cost is small enough to indicate that the generated values and the desired values are close enough. If they are, then at decision point 1725 the learning model results are used as starting values for nodes in a starting state estimation simulation 1510B. If the two sets of values are determined to be too far apart, then at decision point 1730 the learning model node value results are used as starting values for an optimizer simulation such as described with reference to FIG. 5 and the surrounding text. These starting values are assumed to be closer to an eventual optimized value than random values. At operation 1735, the optimization-simulation model is run iteratively until a stop state is achieved. At operation 1740, at an iterative run of the optimization-simulation model, the results are used to train the learning model. FIGS. 11A and 11B give a more detailed look at how operations 1735 and 1740 are performed. At operation 1745, once the optimization-simulation model has reached optimization, the node values generated at the beginning of the last iteration are used as starting node values for a starting state estimation simulation, which is then run. At operation 1750, the simulation model is run and the results of the simulation model are used to modify some aspect of the structure being modeled. This may entail the results of the simulation model being used to run a further model, such as a device simulation model. That device simulation model may then produce a control sequence for one or more devices modeled in the device simulation model. The control sequences produced may then be used to run a device. The control sequences produced may run the device minimizing some aspect of the device, such as energy use. For example, energy use may be minimized by as much as 30%.

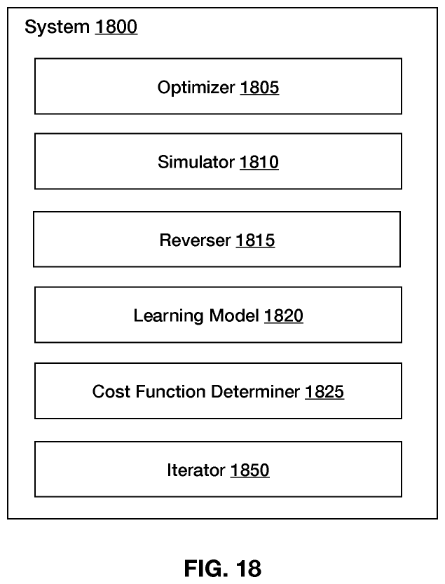

FIG. 18 at 1800 discloses a learning model training system that may be used to warm up a simulation. The system may comprise a processor that may be all or part of a core processing system 330. This processor may also be one or more processors in computing environment 300, 410 that themselves are part of multiple computerized controllers 405 that are networked together in a shared computing system. This shared computing system may share processing power between computing environments. The system also includes a memory in operable communication with the processor, and computing code associated with the processor configured to create a simulator trainer. The memory and/or computing code may be shared between computing environments in a shared computing environment.

Block 1805 disclose an optimizer that determines initial node values for a simulator, the simulator comprising nodes with values. The simulator is shown with reference to FIG. 1 at 110. More detail about, at least, the nodes with values is shown, e.g., with reference to FIG. 12 and the surrounding text. The optimizer and simulator relationship is described, e.g., at FIG. 5 with reference to 510, 511, and 512, and FIG. 8 with reference to 810, 811 and 812.

Block 1810 discloses the simulator. The simulator uses an input time series from time t(−n) to time t(0) as input. Output for the simulator and outputs for the nodes may be an output time series from time t(−n) to time t(0). Inputs with the series t(−n) to t(0) is described, e.g., with reference to FIG. 5 at 505. For example, an example of the input time series from time t(−n) to time t(0) may be the input data 505, shown as running from t=-n to t=0. This input data may be weather or other state data as shown, e.g., with reference to FIG. 8 at 805.

Block 1815 discloses a reverser that reverses the input time series to time t(0) to t(−n), to produce a reversed input time series. An example of this can be seen with reference to FIG. 5 at 505, showing the original time series, and FIG. 7 at 710, showing the reversed time series. The reverser may also reverse the output time series to time t(0) to t(−n). This output time series may be a selected value time series such as shown with reference to FIG. 5 at 515. FIG. 7 at 705 then shows the output (in this case, selected node values) reversed time series.

Block 1820 discloses a learning model that uses the reversed input time series as training input and uses selected values of the output time series at t(−n) as a ground truth for a cost function associated with the learning model. The learning model shown with reference to FIG. 7 takes the input data 505 shown at FIG. 5, reversed (by the reverser 1815), and uses it as input data into the learning model 715. Another example is shown with reference to FIG. 9 at 910.

Block 1825 discloses a cost function determiner. With reference to FIG. 5, the simulator after being run produces selected inside node values 515. These selected inside node values 515 are then measured against a set of desired node values 520. These two sets of node values are measured using a cost function 527 that then produces a cost 525. Similarly, the learning model 715 produces a set of output nodes whose last values (t-n) are compared to simulator node values 620, 720 with a cost function 737 to produce a cost 735. The selected node values 515 and the desired node values 520 are input into a cost function such that the learning model output at time t(−n) is compared with the initial simulator node values. Similar cost function actions are shown with reference to FIGS. 8 and 9.

Block 1850 discloses an iterator. Optimizers, such as optimizers disclosed herein, learn through an iterative process. A series of possible values is chosen as input, the chosen inputs are used by the simulation, in a simulation run, then the output is checked, using a cost function, to see how close it is to a desired output, as explained elsewhere. If not at a stop state, the optimizer then chooses a new set of values for a simulation and the process continues until a stop state is reached. In some embodiments, the iterator controls these iterations. For example, the iterator may run the optimizer, pass the optimized node values to a simulator, run the cost function at the end of the simulation, and determine if a stop state has been reached. If not, then the iterator may have the optimizer determine a subsequent set of optimized node values using the cost. This cycle continues until a stop state is reached. When the stop state is reached, the initial values of the last iteration, e.g., 840 at FIG. 8, are used as input into a starting state estimation simulation, e.g., 210A. In some embodiments, the starting state estimation simulation is run from time t(−n) to time t(0). After the starting state estimation simulation is run, a state simulation (using the same simulator with warmed up node values) may be run forward in time from time t(0) to t(m). This state simulation may produce an output that can be used to eventually produce a control sequence for a device. For example, the results of the state simulation may be used to run another simulation, such as a device simulation. This device simulation may produce a control sequence that can then be used to run a device that was modeled in the device simulation model. The device may then be run using the control sequence produced. This is also explained with reference to FIG. 11B and the surrounding text.

### V. Exemplary Computer-Readable Medium for Training a Simulator

With reference to FIGS. 3 and 4, some embodiments include a configured computer-readable storage medium 365. Medium 365 may include disks (magnetic, optical, or otherwise), RAM, EEPROMS or other ROMs, and/or other configurable memory, including computer-readable media (not directed to a manufactured transient phenomenon, such as an electrical, optical, or acoustical signal). The storage medium which is configured may be a removable storage medium 365 such as a CD, DVD, or flash memory. A program on the storage medium may be run on a processor (e.g., 310, 312, 315, etc.) which is coupled to a memory. Such a memory may be a general-purpose memory (which may be primary, such as RAM, ROM, CMOS, or flash; or may be secondary, such as a CD, a hard drive, an optical disk, or a removable flash drive), can be configured into an embodiment using the computing environment 300, the computerized controller 405, or any combination of the above, in the form of data 380 and instructions 375, read from a source, such as an output device 355, to form a configured medium with data and instructions which upon execution by a processor perform a method for computing traveling comfort information. The configured medium 365 is capable of causing a computer system to perform actions as related herein.

Some embodiments provide or utilize a computer-readable storage medium 365 configured with software 385 which upon execution by at least a central processing unit 310 performs methods and systems described herein.

In view of the many possible embodiments to which the principles of the disclosed invention may be applied, it should be recognized that the illustrated embodiments are only examples of the invention and should not be taken as limiting the scope of the invention. Rather, the scope of the invention is defined by the following claims. We therefore claim as our invention all that comes within the scope and spirit of these claims.

We claim:

1. A computer-enabled system for operating equipment in a controlled space using a warmed-up
digital-twin simulation, the system comprising:
one or more computerized controllers associated with the controlled space;
one or more processors of the one or more computerized controllers; and
one or more memories in operable communication with the one or more processors and storing computer-executable instructions that, when executed by the one or more processors, cause the system to:
receive measured historical state values for one or more sensed locations in the controlled space and historical input state values affecting the controlled space over a historical time interval from time t=(−n) to time t=(0);
execute a trained learning model using, as learning model input, a reversed historical input state time series ordered from time t=(0) to time t=(−n) and a reversed measured historical state time series for the one or more sensed locations ordered from time t=(0) to time t=(−n);
generate, by the trained learning model, starting node state values for a plurality of nodes of a digital-twin simulation model of the controlled space at time t=(−n), wherein the plurality of nodes represent physical portions of the controlled space or equipment in the controlled space and include node properties comprising at least one of temperature, thermal capacitance, layer mass, specific heat capacity, surface area, or resistance;
load the starting node state values generated by the trained learning model into corresponding nodes of the digital-twin simulation model;
run a starting state estimation simulation of the digital-twin simulation model from time t=(−n) to time t=(0), using the historical input state values, to propagate state through the plurality of nodes according to equations associated with the plurality of nodes and thereby produce warmed-up node state values at time t=(0);
run a forward state simulation of the digital-twin simulation model from time t=(0) to a future time t=(m), using the warmed-up node state values at time t=(0) as initial node values for the forward state simulation;
generate, based on output of the forward state simulation, a control sequence for at least one device modeled by the digital-twin simulation model; and
operate the at least one device according to the control sequence to modify a state of the controlled space.

2. The system of claim 1, wherein the trained learning model is trained using training examples generated by an optimizer-simulator loop, and wherein the optimizer-simulator loop comprises repeatedly selecting candidate initial simulator node values, executing the digital-twin simulation model from time t=(−n) to time t=(0) using the candidate initial simulator node values, comparing selected simulator node outputs to ground-truth measured historical state values, and updating the candidate initial simulator node values based on an optimizer cost.

3. The system of claim 2, wherein each execution of the digital-twin simulation model in the optimizer-simulator loop generates a simulator input time series, a selected simulator node-output time series, and a simulator beginning node values at time t=(−n), and wherein training the trained learning model comprises reversing the simulator input time series and the selected simulator node-output time series to generate reverse-time learning-model input and using the simulator beginning node values at time t=(−n) as ground truth for a learning-model cost function.

4. The system of claim 1, wherein the trained learning model comprises a recurrent neural network configured to receive the reversed historical input state time series and the reversed measured historical state time series and output the starting node state values for the plurality of nodes of the digital-twin simulation model.

5. The system of claim 1, wherein the measured historical state values comprise measured temperature values for rooms or zones of a building, and wherein the historical input state values comprise weather data measured over the historical time interval from time t=(−n) to time t=(0).

6. The system of claim 1, wherein the plurality of nodes comprise nodes corresponding to building portions including at least one of a room, wall, window, floor, ceiling, layer of drywall, layer of insulation, stud, outside wall, or inside node.

7. The system of claim 1, wherein at least one of the plurality of nodes comprises a node property that changes during simulation and a node property that remains static during simulation, and wherein the node property that changes during simulation comprises temperature.

8. A non-transitory computer-readable storage medium storing computer-executable instructions that, when executed by one or more processors of one or more computerized controllers associated with a controlled space, cause the one or more computerized controllers to perform operations for operating equipment in the controlled space using a warmed-up digital-twin simulation, the operations comprising:
receiving measured historical state values for one or more sensed locations in the controlled space and historical input state values affecting the controlled space over a historical time interval from time t=(−n) to time t=(0);
executing a trained learning model using, as learning model input, a reversed historical input state time series ordered from time t=(0) to time t=(−n) and a reversed measured historical state time series for the one or more sensed locations ordered from time t=(0) to time t=(−n);
generating, by the trained learning model, starting node state values for a plurality of nodes of a digital-twin simulation model of the controlled space at time t=(−n), wherein the plurality of nodes represent physical portions of the controlled space or equipment in the controlled space and include node properties comprising at least one of temperature, thermal capacitance, layer mass, specific heat capacity, surface area, or resistance;
loading the starting node state values generated by the trained learning model into corresponding nodes of the digital-twin simulation model;
running a starting state estimation simulation of the digital-twin simulation model from time t=(−n) to time t=(0), using the historical input state values, to propagate state through the plurality of nodes according to equations associated with the plurality of nodes and thereby produce warmed-up node state values at time t=(0);
running a forward state simulation of the digital-twin simulation model from time t=(0) to a future time t=(m), using the warmed-up node state values at time t=(0) as initial node values for the forward state simulation;
generating, based on output of the forward state simulation, a control sequence for at least one device modeled by the digital-twin simulation model; and
operating the at least one device according to the control sequence to modify a state of the controlled space.

9. The non-transitory computer-readable storage medium of claim 8, wherein the trained learning model is trained using training examples generated by an optimizer-simulator loop, and wherein the optimizer-simulator loop comprises repeatedly selecting candidate initial simulator node values, executing the digital-twin simulation model from time t=(−n) to time t=(0) using the candidate initial simulator node values, comparing selected simulator node outputs to ground-truth measured historical state values, and updating the candidate initial simulator node values based on an optimizer cost.

10. The non-transitory computer-readable storage medium of claim 9, wherein each execution of the digital-twin simulation model in the optimizer-simulator loop generates a simulator input time series, a selected simulator node-output time series, and simulator beginning node values at time t=(−n), and wherein training the trained learning model comprises reversing the simulator input time series and the selected simulator node-output time series to generate reverse-time learning-model input and using the simulator beginning node values at time t=(−n) as ground truth for a learning-model cost function.

11. The non-transitory computer-readable storage medium of claim 10, wherein training the trained learning model further comprises comparing learning-model output values at time t=(−n) with the simulator beginning node values at time t=(−n) to determine a learning-model cost and backpropagating the learning-model cost through the trained learning model to update one or more parameters of the trained learning model.

12. A computer-implemented method for operating equipment in a controlled space using a warmed-up digital-twin simulation, the method comprising:
receiving, by one or more computerized controllers associated with a controlled space and configured to communicate with at least one device in the controlled space, measured historical state values for one or more sensed locations in the controlled space and historical input state values affecting the controlled space over a historical time interval from time t=(−n) to time t=(0);
executing, by the one or more computerized controllers, a trained learning model using, as learning model input, a reversed historical input state time series ordered from time t=(0) to time t=(−n) and a reversed measured historical state time series for the one or more sensed locations ordered from time t=(0) to time t=(−n);
generating, by the trained learning model, starting node state values for a plurality of nodes of a digital-twin simulation model of the controlled space at time t=(−n), wherein the plurality of nodes represent physical portions of the controlled space or equipment in the controlled space and include node properties comprising at least one of temperature, thermal capacitance, layer mass, specific heat capacity, surface area, or resistance;
loading, by the one or more computerized controllers, the starting node state values generated by the trained learning model into corresponding nodes of the digital-twin simulation model;
running, by the one or more computerized controllers, a starting state estimation simulation of the digital-twin simulation model from time t=(−n) to time t=(0), using the historical input state values, to propagate state through the plurality of nodes according to equations associated with the plurality of nodes and thereby produce warmed-up node state values at time t=(0);
running, by the one or more computerized controllers, a forward state simulation of the digital-twin simulation model from time t=(0) to a future time t=(m), using the warmed-up node state values at time t=(0) as initial node values for the forward state simulation;
generating, by the one or more computerized controllers based on output of the forward state simulation, a control sequence for the at least one device modeled by the digital-twin simulation model; and
communicating, by the one or more computerized controllers, the control sequence to the at least one device to operate the at least one device and modify a state of the controlled space.

13. The method of claim 12, wherein the trained learning model is trained using training examples generated by an optimizer-simulator loop, and wherein the optimizer-simulator loop comprises repeatedly selecting candidate initial simulator node values, executing the digital-twin simulation model from time t=(−n) to time t=(0) using the candidate initial simulator node values, comparing selected simulator node outputs to ground-truth measured historical state values, and updating the candidate initial simulator node values based on an optimizer cost.

14. The method of claim 13, wherein each execution of the digital-twin simulation model in the optimizer-simulator loop generates a simulator input time series, a selected simulator node-output time series, and simulator beginning node values at time t=(−n), and wherein training the trained learning model comprises reversing the simulator input time series and the selected simulator node-output time series to generate reverse-time learning-model input and using the simulator beginning node values at time t=(−n) as ground truth for a learning-model cost function.

15. The method of claim 14, wherein training the trained learning model further comprises comparing learning-model output values at time t=(−n) with the simulator beginning node values at time t=(−n) to determine a learning-model cost and backpropagating the learning-model cost through the trained learning model to update one or more parameters of the trained learning model.

16. The method of claim 12, wherein the trained learning model comprises a recurrent neural network configured to receive the reversed historical input state time series and the reversed measured historical state time series and output the starting node state values for the plurality of nodes of the digital-twin simulation model.

17. The method of claim 12, wherein the measured historical state values comprise measured temperature values for rooms or zones of a building, and wherein the historical input state values comprise weather data measured over the historical time interval from time t=(−n) to time t=(0).

18. The method of claim 12, wherein the plurality of nodes comprise nodes corresponding to building portions including at least one of a room, wall, window, floor, ceiling, layer of drywall, layer of insulation, stud, outside wall, or inside node.

19. The method of claim 12, wherein at least one of the plurality of nodes comprises a node property that changes during simulation and a node property that remains static during simulation, and wherein the node property that changes during simulation comprises temperature.

20. The method of claim 12, wherein the at least one device comprises at least one of an air conditioner, heater, boiler, movable vent, HVAC device, lighting device, lock, speaker, or sensor.
